(19) United States
(12) Patent Application Publication
(10) Pub. No.: US 2026/0025981 A1
(43) Pub. Date: Jan. 22, 2026

(54) SEMICONDUCTOR DEVICE INCLUDING VERTICAL CHANNEL TRANSISTORS

(71) Applicant: SAMSUNG ELECTRONICS CO., LTD., Suwon-si (KR)

(72) Inventors: Heonjun Ha, Suwon-si (KR); Changsik Kim, Suwon-si (KR); Jihee Jun, Suwon-si (KR); Chanhee Han, Suwon-si (KR)

(73) Assignee: SAMSUNG ELECTRONICS CO., LTD., Suwon-si (KR)

(21) Appl. No.: 19/016,538

(22) Filed: Jan. 10, 2025

(30) Foreign Application Priority Data
Jul. 19, 2024 (KR) 10-2024-0095845

(51) Int. Cl. H10B 12/00

(52) U.S. Cl. CPC H10B 12/482; H10B 12/315; H10B 12/485

(57) ABSTRACT

A semiconductor device includes a bit line extending in a first direction, a semiconductor pattern on the bit line, a first word line and a second word line, and back-gate electrodes. The semiconductor pattern includes a first vertical portion and a second vertical portion, which are spaced apart from each other in the first direction, and a horizontal portion, which is provided between the first vertical portion and the second vertical portion and is configured to couple the first vertical portion with the second vertical portion. The first word line and the second word line are spaced apart from each other in the first direction between the first vertical portion and the second vertical portion, and are disposed on inner side surfaces of the first vertical portion and the second vertical portion, respectively, and are extended in a second direction.

### CROSS-REFERENCE TO RELATED APPLICATIONS

This application claims benefit of priority under 35 U.S.C. § 119 to Korean Patent Application No. 10-2024-0095845, filed on Jul. 19, 2024, in the Korean Intellectual Property Office, the disclosure of which is incorporated by reference herein in its entirety.

### BACKGROUND

The present disclosure relates generally to a semiconductor device, and more particularly, to a semiconductor device including vertical channel transistors and a method of fabricating the same.

As semiconductor devices may be scaled down and/or reduced in size, fabrication technologies that may be capable of increasing an integration density of the semiconductor devices, improving an operation speed, and/or improving a production yield, may need to be developed. In an attempt to address some of these constraints, transistors with vertical channel regions may been suggested to potentially increase an integration density of a semiconductor device and/or improve the resistance characteristics and current driving ability of the transistor.

### SUMMARY

One or more example embodiments of the present disclosure provide a semiconductor device with improved electrical and reliability characteristics, when compared to related semiconductor devices, and a method of fabricating the same.

According to an aspect of the present disclosure, a semiconductor device includes a bit line extending in a first direction, a semiconductor pattern on the bit line, a first word line and a second word line, and back-gate electrodes. The semiconductor pattern includes a first vertical portion and a second vertical portion, which are spaced apart from each other in the first direction, and a horizontal portion, which is provided between the first vertical portion and the second vertical portion and is configured to couple the first vertical portion with the second vertical portion. The first word line and the second word line are spaced apart from each other in the first direction between the first vertical portion and the second vertical portion, and are disposed on inner side surfaces of the first vertical portion and the second vertical portion, respectively, and are extended in a second direction. The back-gate electrodes are spaced apart from each other in the first direction with the first vertical portion and the second vertical portion interposed therebetween, and are extended in the second direction. The first direction and the second direction are parallel to an uppermost surface of the bit line and the first direction and the second direction are non-parallel to each other. The back-gate electrodes are disposed on outer side surfaces of the first vertical portion and the second vertical portion, respectively.

According to an aspect of the present disclosure, a semiconductor device includes a bit line extending in a first direction, a back-gate electrode provided on the bit line and extended in a second direction to cross the bit line, a first semiconductor vertical portion and a second semiconductor vertical portion, which are spaced apart from each other in the first direction with the back-gate electrode interposed therebetween, a first word line, which is spaced apart from the back-gate electrode with the first semiconductor vertical portion interposed therebetween, and is extended in the second direction, a second word line, which is spaced apart from the back-gate electrode with the second semiconductor vertical portion interposed therebetween, and is extended in the second direction, and semiconductor horizontal portions, which are respectively extended from a first lower portion of the first semiconductor vertical portion and a second lower portion of the second semiconductor vertical portion into regions between the first word line and the second word line and the bit line.

According to an aspect of the present disclosure, a semiconductor device includes a bit line extending in a first direction, semiconductor patterns provided on the bit line and spaced apart from each other in the first direction, back-gate electrodes, which are provided between the semiconductor patterns, first word lines, which are respectively disposed adjacent to the first vertical portion and are extended in the second direction, second word lines, which are respectively disposed adjacent to the second vertical portion and are extended in the second direction, storage node contacts disposed on the first vertical portion and the second vertical portion, respectively, landing pads disposed on the storage node contacts, respectively, and data storage patterns disposed on the landing pads, respectively. Each of the semiconductor patterns includes a first vertical portion and a second vertical portion, which are spaced apart on each other in the first direction, and a horizontal portion, which is provided between the first vertical portion and the second vertical portion and is configured to couple the first vertical portion with the second vertical portion. The back-gate electrodes are extended in a second direction, and are spaced apart from each other in the first direction. The first direction and the second direction are parallel to an uppermost surface of the bit line and are non-parallel to each other.

Additional aspects may be set forth in part in the description which follows and, in part, may be apparent from the description, and/or may be learned by practice of the presented embodiments.

### BRIEF DESCRIPTION OF DRAWINGS

The above and other aspects, features, and advantages of certain embodiments of the present disclosure may be more apparent from the following description taken in conjunction with the accompanying drawings, in which:

FIG. 1 is a block diagram illustrating a semiconductor device, according to an embodiment;

FIGS. 2 and 3 are perspective views schematically illustrating a semiconductor device, according to an embodiment;

FIG. 4 is a plan view illustrating a semiconductor device, according to an embodiment;

FIGS. 5A, 5B, and 5C are sectional views corresponding to lines A-A′, B-B′, and C-C′ of FIG. 4, according to an embodiment;

FIGS. 6A to 17C are sectional views illustrating a method of fabricating a semiconductor device, according to an embodiment;

FIG. 18 is a sectional view illustrating a semiconductor device, according to an embodiment;

FIGS. 19 and 20 are sectional views illustrating a method of fabricating a semiconductor device, according to an embodiment;

FIG. 21 is a plan view illustrating a semiconductor device, according to an embodiment;

FIGS. 22A, 22B, and 22C are sectional views, which are taken along lines A-A′, B-B′, and C-C′ of FIG. 21 to illustrate a semiconductor device, according to an embodiment; and

FIGS. 23A to 25C are sectional views illustrating a method of fabricating a semiconductor device, according to an embodiment.

### DETAILED DESCRIPTION

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

It is to be understood that when an element or layer is referred to as being “over,” “above,” “on,” “below,” “under,” “beneath,” “connected to” or “coupled to” another element or layer, it may be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

The terms “upper,” “middle”, “lower”, and the like may be replaced with terms, such as “first,” “second,” third” to be used to describe relative positions of elements. The terms “first,” “second,” third” may be used to describe various elements but the elements are not limited by the terms and a “first element” may be referred to as a “second element”. Alternatively or additionally, the terms “first”, “second”, “third”, and the like may be used to distinguish components from each other and do not limit the present disclosure. For example, the terms “first”, “second”, “third”, and the like may not necessarily involve an order or a numerical meaning of any form.

As used herein, when an element or layer is referred to as “covering”, “overlapping”, or “surrounding” another element or layer, the element or layer may cover at least a portion of the other element or layer, where the portion may include a fraction of the other element or may include an entirety of the other element. Similarly, when an element or layer is referred to as “penetrating” another element or layer, the element or layer may penetrate at least a portion of the other element or layer, where the portion may include a fraction of the other element or may include an entire dimension (e.g., length, width, depth) of the other element.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

As used herein, each of the terms “(Ba,Sr) RuO₃”, “Al₂O₃”, “CaRuO₃”, “CoSi₂”, “HfO₂”, “HfSiO”, “HfSiON”, “HfTaO”, “HfTiO”, “HfZrO”, “IrOₓ”, “LSCo”, “NbN”, “NiSi”, “PtO”, “RuOₓ”, “RuTiN”, “Si₃N₄”, “SiC”, “SiCN”, “SiO”, “SiOₓN_{y}”, “SrRuO₃”, “TaN”, “TaSi”, “TaSiN”, “TiAl”, “TiAlN”, “TiN”, “TiSi₂”, “TiSiN”, “WN”, “ZrO₂”, and the like may refer to a material made of elements included in each of the terms and is not a chemical formula representing a stoichiometric relationship.

Hereinafter, various embodiments of the present disclosure are described with reference to the accompanying drawings.

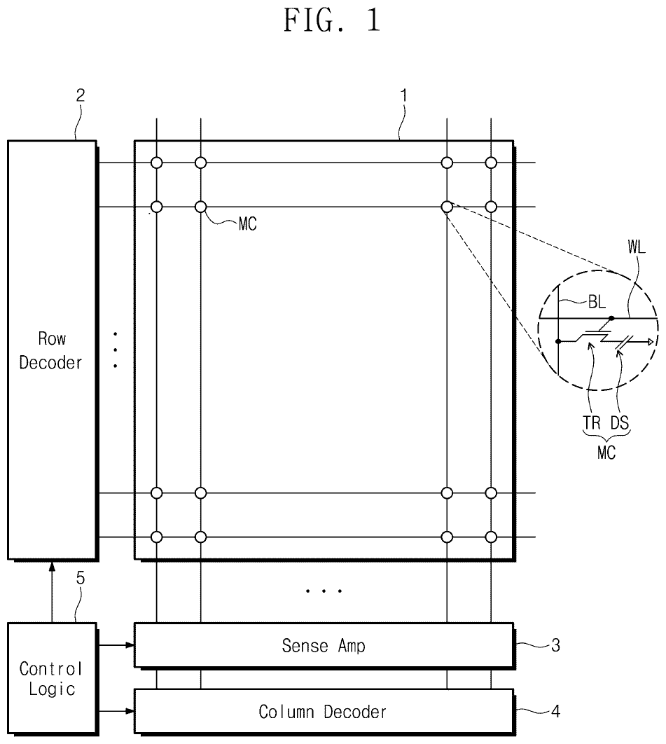

FIG. 1 is a block diagram illustrating a semiconductor device, according to an embodiment.

Referring to FIG. 1, a semiconductor device may include a memory cell array 1, a row decoder 2, a sense amplifier 3, a column decoder 4, and a control logic circuit 5.

The memory cell array 1 may include a plurality of memory cells MC, which may be two-and/or three-dimensionally arranged. Each of the memory cells MC may be provided between and connected to a word line WL and a bit line BL, which may be provided to cross each other.

Each of the memory cells MC may include a selection element TR and a data storage element DS. The selection element TR and the data storage element DS may be electrically connected to each other. The selection element TR may be connected to both the word line WL and the bit line BL. That is, the selection element TR may be provided at an intersection of the word lines WL and the bit lines BL.

The selection element TR may include or may be implemented by a field effect transistor (FET). The data storage element DS may include or may be implemented by a capacitor, a magnetic tunnel junction (MJT) device, a variable resistor, or the like. For example, the selection element TR may be a transistor whose gate, source, and drain terminals may be connected to the word line WL, the bit line BL, and the data storage element DS, respectively.

The row decoder 2 may be configured to decode address information, which may be input from the outside, and to select one of the word lines WL of the memory cell array 1, based on the decoded address information. The address information decoded by the row decoder 2 may be provided to a row driver, and in this case, the row driver may provide respective voltages to the selected one of the word lines WL and the unselected ones of the word lines WL, in response to the control of a control circuit.

The sense amplifier 3 may be configured to sense, amplify, and/or output a difference in voltage between one of the bit lines BL, which may be selected based on address information decoded by the column decoder 4, and a reference bit line.

The column decoder 4 may establish a data transmission path between the sense amplifier 3 and an external device (e.g., a memory controller). The column decoder 4 may be configured to decode address information, which may be input from the outside, and to select one of the bit lines BL, based on the decoded address information.

The control logic circuit 5 may generate control signals, which may be used to control an operation of writing or reading data to or from the memory cell array 1.

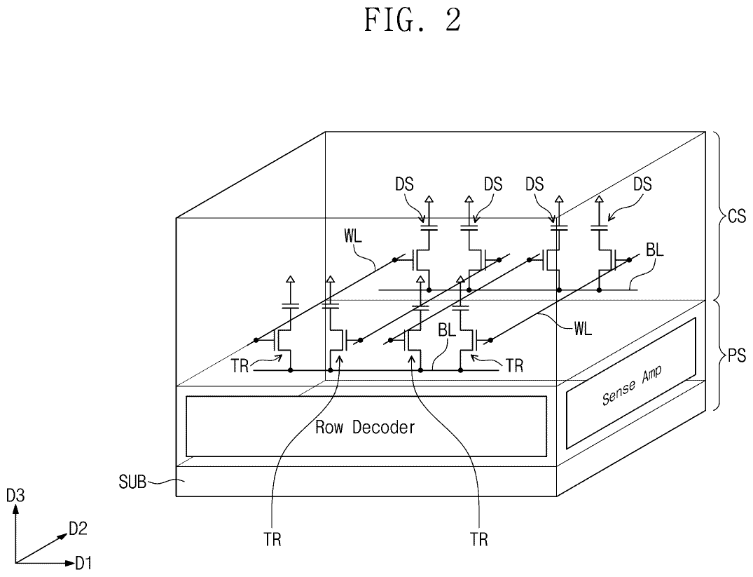

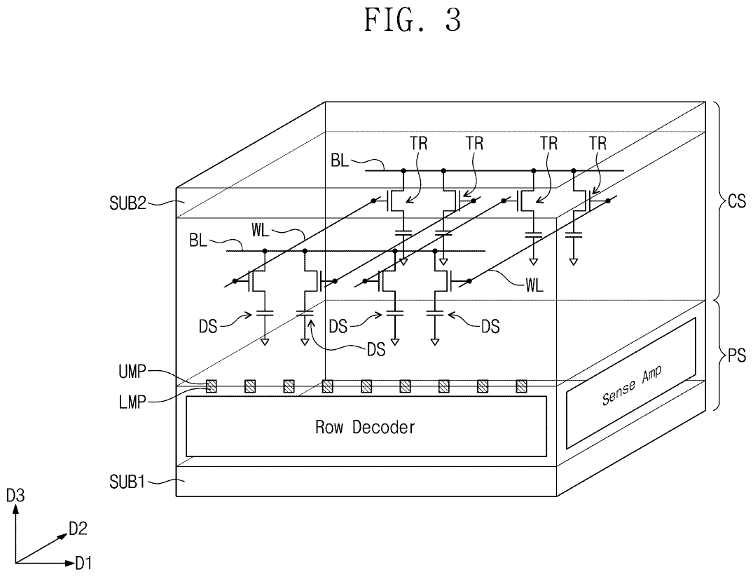

FIGS. 2 and 3 are perspective views schematically illustrating a semiconductor device, according to an embodiment.

Referring to FIGS. 2 and 3, the semiconductor device may include a peripheral circuit structure PS and a cell structure CS, which may be connected to each other.

The peripheral circuit structure PS may include core and peripheral circuits, which may be formed on a substrate SUB. The core and peripheral circuits may include the row decoder 2, the column decoder 4, the sense amplifier 3, and the control logic circuit 5 described with reference to FIG. 1.

The cell structure CS may include the memory cell array 1 of FIG. 1, in which the memory cells MC of FIG. 1 may be two-and/or three-dimensionally arranged. Each of the memory cells MC of FIG. 1 may include the selection element TR and the data storage element DS, as described above.

In an embodiment, the selection element TR of each of the memory cells MC of FIG. 1 may include a vertical channel transistor (VCT). The vertical channel transistor may have a channel region whose lengthwise direction may be substantially normal to a top surface of the substrate SUB. The data storage element DS of each of the memory cells MC of FIG. 1 may include a capacitor.

In the embodiment of FIG. 2, the peripheral circuit structure PS may be provided on the substrate SUB, and the cell structure CS may be provided on the peripheral circuit structure PS.

In the embodiment of FIG. 3, the peripheral circuit structure PS may be provided on a first substrate SUB1, and the cell structure CS may be provided on a second substrate SUB2. The first and second substrates SUB1 and SUB2 may be provided to face each other.

First metal pads LMP may be provided in the uppermost portion of the peripheral circuit structure PS. The first metal pads LMP may be electrically connected to the core and peripheral circuits (e.g., the row decoder 2, the sense amplifier 3, the column decoder 4, and the control logic circuit 5 of FIG. 1).

Second metal pads UMP may be provided in the lowermost portion of the cell structure CS. The second metal pads UMP may be electrically connected to the memory cell array 1 of FIG. 1. The second metal pads UMP may be directly boned to (e.g., in direct contact with) the first metal pads LMP of the peripheral circuit structure PS.

According to one or more embodiments, the control logic circuit 5 may be implemented by at least one processor such as a central processing unit (CPU) and/or another type of microprocessor, and an internal memory to perform the functions described herein by loading corresponding computer code or instructions stored in an internal or external storage device to the internal memory and execute the computer code or instructions. According to one or more embodiments, the row decoder 2, the sense amplifier 3 and the column decoder 4 may each be implemented by dedicated hardware circuit including one or more of logic gates or circuits, registers, memories, interface circuits, etc. configured to perform the functions described herein in association with the control logic circuit 5. According to one or more embodiments, the row decoder 2, the sense amplifier 3, the column decoder 4, and the control logic circuit 5 may be implemented in respective semiconductor chips or a single semiconductor chip.

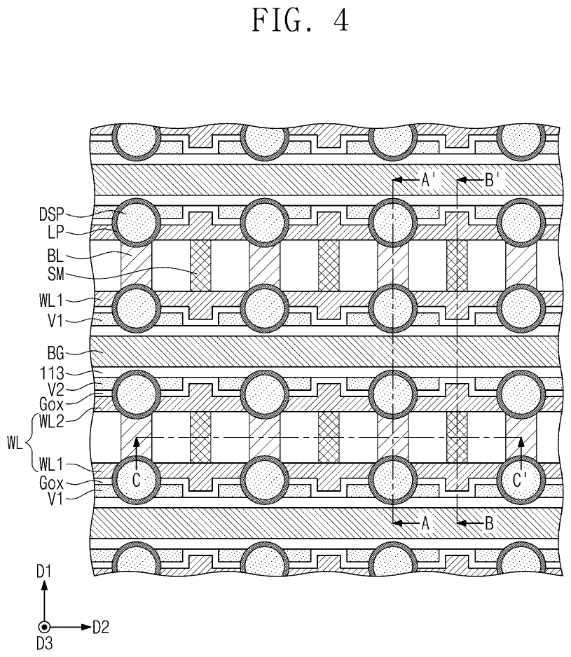

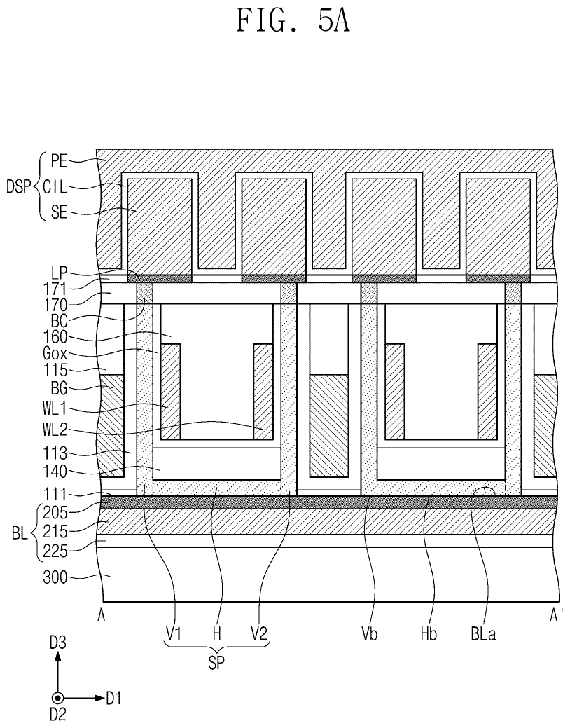

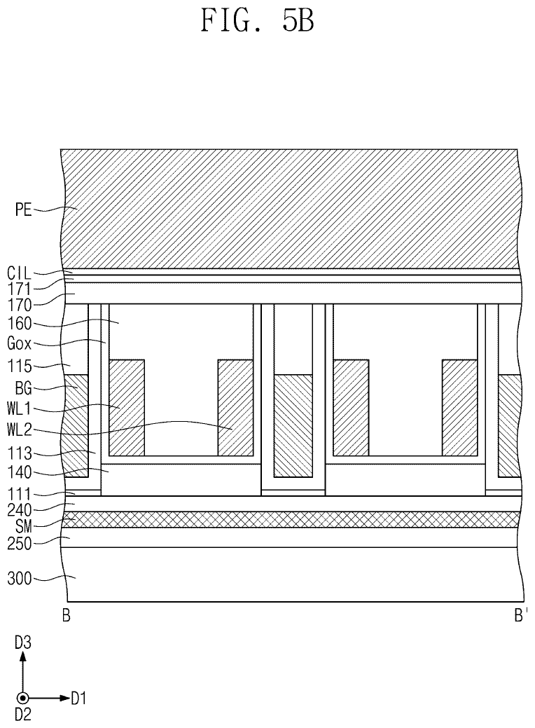

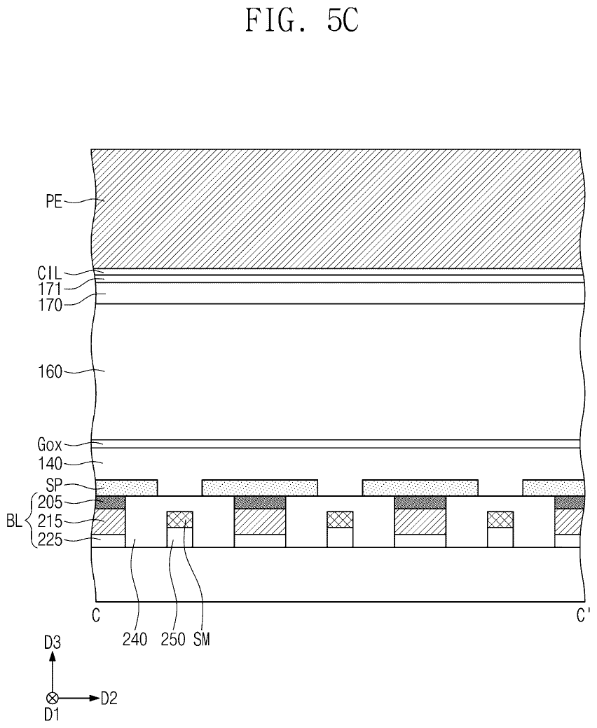

FIG. 4 is a plan view illustrating a semiconductor device, according to an embodiment. FIGS. 5A, 5B, and 5C are sectional views corresponding to lines A-A′, B-B′, and C-C′ of FIG. 4, according to an embodiment.

A semiconductor memory device, according to an embodiment, may include memory cells, each of which may include a vertical channel transistor (VCT).

Referring to FIGS. 4, 5A, 5B, and 5C, the bit line BL, which is extended in a first direction D1, may be disposed on a substrate 300. In an embodiment, a plurality of bit lines BL may be provided. The bit lines BL may be spaced apart from each other in a second direction D2. In the present disclosure, the first direction D1 and the second direction D2 may be parallel to the uppermost surface BLa of the bit line BL and may not be parallel to each other. A third direction D3 may be a vertical direction D3 that may be perpendicular to the uppermost surface BLa of the bit line BL. For example, the first to third directions D1, D2, and D3 may be orthogonal to each other.

The substrate 300 may be formed of and/or or include at least one of semiconductor materials (e.g., a silicon wafer), insulating materials (e.g., glass), or a semiconductor or conductive material covered with an insulating material.

Each of the bit lines BL may include a hard mask pattern 225, a metal pattern 215, and a polysilicon pattern 205, which may be sequentially stacked on the substrate 300. The hard mask patterns 225 of the bit lines BL may be in contact with the substrate 300. The metal pattern 215 may include at least one of conductive metal nitride materials (e.g., titanium nitride (TiN) and tantalum nitride (TaN)) or metallic materials (e.g., tungsten (W), titanium (Ti), and tantalum (Ta)). The hard mask pattern 225 may include at least one of insulating materials (e.g., silicon nitride (Si₃N₄), silicon oxynitride (SiOₓN_{y}), or the like). In an embodiment, the metal pattern 215 may include at least one of metal silicide materials (e.g., titanium silicide (TiSi₂), cobalt silicide (CoSi₂), nickel silicide (NiSi), or the like). However, the present disclosure is not limited in this regard.

Shielding structures SM may be respectively disposed between the bit lines BL. The shielding structures SM may be extended in the first direction D1. The shielding structures SM may be formed of and/or include at least one of conductive materials (e.g., metallic materials). The shielding structures SM may be disposed between insulating layers (e.g., first insulating layers 240 and second insulating layers 250) and may have top surfaces that may be located at a lower height than the uppermost surfaces BLa of the bit lines BL. Each of the first and second insulating layers 240 and 250 may be a multi-layered structure including a plurality of stacked insulating layers and may include at least one of, for example, silicon oxide (SiO), silicon nitride (Si₃N₄), silicon oxynitride (SiOₓN_{y}), and low-k dielectric materials.

In an embodiment, the shielding structures SM may be formed of a conductive material, and an air gap or void may be formed in the shielding structures SM. In another embodiment, air gaps may be provided in placed of the shielding structures SM.

A semiconductor pattern SP may be disposed on the bit line BL. In an embodiment, a plurality of semiconductor patterns SP may be provided. The semiconductor patterns SP may be spaced apart from each other in the first and second directions D1 and D2.

The semiconductor pattern SP may include a first vertical portion V1 and a second vertical portion V2, which may be spaced apart from each other in the first direction D1, and a horizontal portion H, which may be provided between the first and second vertical portions V1 and V2 to connect the first and second vertical portions V1 and V2 to each other. The horizontal portion H may be provided adjacent to lower portions of the first and second vertical portions V1 and V2 and may connect the first and second vertical portions V1 and V2 to each other. The first and second vertical portions V1 and V2 may be referred to as a first semiconductor vertical portion V1 and a second semiconductor vertical portion V2, respectively. The horizontal portion H may be referred to as a semiconductor horizontal portion H.

The semiconductor pattern SP may be formed of a single crystalline semiconductor material. For example, the semiconductor pattern SP may be formed of single crystalline silicon. However, the present disclosure is not limited in this regard, and the semiconductor pattern SP may be formed of other materials.

The first and second vertical portions V1 and V2 may be extended in the vertical direction D3. In an embodiment, the first vertical portion V1, the second vertical portion V2, and the horizontal portion H may have a substantially similar and/or the same width in the second direction D2. Widths of the first vertical portion V1, the second vertical portion V2, and the horizontal portion H in the second direction D2 may be larger than a width of the bit line BL in the second direction D2.

A top surface of the bit line BL may be straightly extended in the first direction D1. A height of the top surface of the bit line BL may be maintained to be constant, regardless of the position in the first direction D1. That is, the height of the top surface of the bit line BL may be allowed to vary by a relatively small margin of error. In an embodiment, the top surface of the bit line BL may be the uppermost surface BLa of the bit line BL.

The horizontal portion H of the semiconductor pattern SP may be provided on the top surface of the bit line BL. A bottom surface Hb of the horizontal portion H may be in contact with the uppermost surface BLa of the bit line BL and may be located at the same height as the uppermost surface BLa of the bit line BL. In an embodiment, bottom surfaces Vb of the first and second vertical portions V1 and V2 may be in contact with the uppermost surface BLa of the bit line BL and may be located at the same height as the uppermost surface BLa of the bit line BL. The bottom surfaces Vb of the first and second vertical portions V1 and V2 may be coplanar with the bottom surface Hb of the horizontal portion H.

The horizontal portion H may include a common source/drain region, and upper portions of the first and second vertical portions V1 and V2 may include first and second source/drain regions, respectively. The first vertical portion V1 may include a first channel region between the common source/drain region and the first source/drain region, and the second vertical portion V2 may include a second channel region between the common source/drain region and the second source/drain region. Each of the first and second vertical portions V1 and V2 may be electrically connected to the bit line BL. In the semiconductor device, according to an embodiment, a pair of vertical channel transistors may have a structure sharing one bit line BL.

The word line WL may be disposed between the first and second vertical portions V1 and V2. The word line WL may be disposed on the horizontal portion H. In an embodiment, a plurality of word lines WL may be provided. The word lines WL may be extended in the second direction D2 and may be spaced apart from each other in the first direction D1.

Each of the word lines WL may include a first word line WL1 and a second word line WL2, which are spaced apart from each other in the first direction D1. The first word line WL1 may be disposed adjacent to the first vertical portion V1. The second word line WL2 may be disposed adjacent to the second vertical portion V2.

The first word line WL1 may be disposed on an inner side surface of the first vertical portion V1 facing the second vertical portion V2. The first word line WL1 may be adjacent to the first channel region of the first vertical portion V1 and may be used to control the first channel region. The first word line WL1 may be spaced apart from a back-gate electrode BG, with the first vertical portion V1 interposed therebetween.

The second word line WL2 may be disposed on an inner side surface of the second vertical portion V2 facing the first vertical portion V1. The second word line WL2 may be adjacent to the second channel region of the second vertical portion V2 and may be used to control the second channel region. The second word line WL2 may be spaced apart from a back-gate electrode BG, with the second vertical portion V2 interposed therebetween.

The word line WL may be formed of and/or may include at least one of doped polysilicon, metallic materials (e.g., aluminum (Al), copper (Cu), titanium (Ti), tantalum (Ta), ruthenium (Ru), tungsten (W), molybdenum (Mo), platinum (Pt), nickel (Ni), cobalt (Co)), conductive metal nitride materials (e.g., titanium nitride (TiN), tantalum nitride (TaN), tungsten nitride (WN), niobium nitride (NbN), titanium aluminide (TiAl), titanium aluminum nitride (TiAlN), titanium silicide (TiSi₂), titanium silicon nitride (TiSiN), tantalum silicide (TaSi), tantalum silicon nitride (TaSiN), ruthenium titanium nitride (RuTiN)), conductive metal silicide materials, or conductive metal oxide materials (e.g., platinum oxide (PtO), ruthenium oxide (RuOₓ), iridium oxide (IrOₓ), strontium ruthenate (SrRuO₃ or SRO), barium-strontium ruthenate ((Ba,Sr)RuO₃ or BSRO), calcium ruthenate (CaRuO₃ or CRO), lanthanum strontium cobaltite (LSCo)), or the like. However, the present disclosure is not limited to these examples. The word line WL may be provided to have a single- or multi-layered structure formed of the afore-described materials. In an embodiment, the word line WL may be formed of and/or may include at least one of two-dimensional semiconductor materials (e.g., graphene, carbon nanotube, or combinations thereof).

A back-gate electrode BG may be disposed on the bit line BL to cross the bit line BL and to extend in the second direction D2. The back-gate electrode BG may be disposed between the semiconductor patterns SP, which may be adjacent to each other in the first direction D1. In an embodiment, a plurality of back-gate electrodes BG may be provided. The back-gate electrodes BG may be spaced apart from each other in the first direction D1. That is, the back-gate electrodes BG may be spaced apart from each other in the first direction D1, with the semiconductor patterns SP arranged in the second direction D2 interposed therebetween.

The back-gate electrode BG may be disposed between the first and second vertical portions V1 and V2, which may respectively be included in two different ones of the semiconductor patterns SP that may be adjacent to each other in the first direction D1. The back-gate electrode SP may be disposed on an outer side surface of the first or second vertical portion V1 or V2 of the semiconductor pattern SP. That is, the back-gate electrodes BG may be respectively disposed on the outer side surface of the first vertical portion V1 of the semiconductor pattern SP and the outer side surface of the second vertical portion V2 of the semiconductor pattern SP, with each semiconductor pattern SP interposed therebetween. The back-gate electrodes BG may be vertically overlapped with the horizontal portion H of the semiconductor pattern SP, when viewed in a plan view.

The back-gate electrode BG may include at least one of doped polysilicon, conductive metal nitride (e.g., titanium nitride (TiN), or tantalum nitride (TaN)), metallic materials (e.g., tungsten (W), titanium (Ti), or tantalum (Ta)), conductive metal silicide materials (e.g., titanium silicide (TiSi₂), tantalum silicide (TaSi), nickel silicide (NiSi), cobalt silicide (CoSi)), conductive metal oxide materials (e.g., platinum oxide (PtO), iridium oxide (IrOₓ), ruthenium oxide (RuOₓ)), or combinations thereof. However, the present disclosure is not limited to these examples.

A first insulating pattern 111 may be disposed between the bit line BL and the back-gate electrode BG. The first insulating pattern 111 may be disposed between the semiconductor patterns SP, which may be adjacent to each other in the first direction D1. In an embodiment, a plurality of first insulating patterns 111 may be provided. The first insulating patterns 111 may be extended in the second direction D2 and may be spaced apart from each other in the first direction D1. The first insulating pattern 111 may include at least one of, for example, silicon oxide (SiO), silicon nitride (SiN), silicon oxynitride (SiON), or low-k dielectric materials. However, the present disclosure is not limited to these examples.

A back-gate insulating pattern 113 may be interposed between the back-gate electrode BG and the first and second vertical portions V1 and V2. The back-gate insulating pattern 113 may be extended into a space between the back-gate electrode BG and the first insulating pattern 111. Between the back-gate electrode BG and the first and second vertical portions V1 and V2, the back-gate insulating pattern 113 may be extended in the vertical direction D3. That is, the back-gate insulating pattern 113 may include vertical portions and a horizontal portion connecting the vertical portions, and here, the vertical portions may be provided to cover two side surfaces of the back-gate electrode BG, which are opposite to each other in the first direction D1, and may be extended in the vertical direction D3. In an embodiment, a plurality of back-gate insulating patterns 113 may be provided. The back-gate insulating patterns 113 may be extended in the second direction D2 and may be spaced apart from each other in the first direction D1.

The back-gate insulating pattern 113 may be formed of or include at least one of silicon oxide (SiO), silicon oxynitride (SiON), or high-k dielectric materials whose dielectric constants are higher than that of silicon oxide (SiO). The high-k dielectric material may include metal oxide materials and/or metal oxynitride materials. For example, the high-k dielectric material for the back-gate insulating pattern 113 may include at least one of hafnium oxide (HfO₂), hafnium silicate (HfSiO), hafnium silicon oxynitride (HfSiON), hafnium tantalum oxide (HfTaO), hafnium titanate (HfTiO), (HfZrO), hafnium zirconium oxide (ZrO₂), aluminum oxide (Al₂O₃), or the like. However, the present disclosure is not limited to these examples.

A back-gate capping pattern 115 may be disposed on the back-gate electrode BG. The back-gate capping pattern 115 may be disposed between the vertical portions of the back-gate insulating pattern 113. A top surface of the back-gate capping pattern 115 may be coplanar with top surfaces of the vertical portions of the back-gate insulating pattern 113 and top surfaces of the vertical portions V1 and V2 of the semiconductor pattern SP. The back-gate capping pattern 115 may include an insulating material. In an embodiment, a plurality of back-gate capping patterns 115 may be provided. The back-gate capping patterns 115 may be extended in the second direction D2 and may be spaced apart from each other in the first direction D1.

A gate insulating pattern Gox may be interposed between the semiconductor pattern SP and the word line WL. The gate insulating pattern Gox may be extended into a space between the word line WL and a second insulating pattern 140. For example, the gate insulating pattern Gox may be interposed between the inner side surface of the first vertical portion V1 and the first word line WL1 and between the inner side surface of the second vertical portion V2 and the second word line WL2 and may be extended in the vertical direction D3. That is, the gate insulating pattern Gox may include vertical portions, which may be provided between the word line WL and the first and second vertical portions V1 and V2 of the semiconductor pattern SP and may be extended in the vertical direction D3. The gate insulating pattern Gox may further include a horizontal portion connecting the vertical portions. The word line WL may be spaced apart from the semiconductor pattern SP by the gate insulating pattern Gox.

The gate insulating pattern Gox may be formed of and/or may include at least one of silicon oxide (SiO), silicon oxynitride (SiON), or high-k dielectric materials whose dielectric constants are higher than that of silicon oxide. The high-k dielectric material may include metal oxide materials and/or metal oxynitride materials. For example, the high-k dielectric material for the gate insulating pattern Gox may include at least one of hafnium oxide (HfO₂), hafnium silicate (HfSiO), hafnium silicon oxynitride (HfSiON), hafnium tantalum oxide (HfTaO), hafnium titanate (HfTiO), (HfZrO), hafnium zirconium oxide (ZrO₂), aluminum oxide (Al₂O₃), or the like. However, the present disclosure is not limited to these examples.

A second insulating pattern 140 may be disposed between the horizontal portion of the gate insulating pattern Gox and the first insulating layer 240. The second insulating pattern 140 may cover the horizontal portion H of the semiconductor pattern SP. The second insulating pattern 140 may be disposed between the back-gate electrodes BG. In an embodiment, a plurality of second insulating patterns 140 may be provided. The second insulating patterns 140 may be extended in the second direction D2 and may be spaced apart from each other in the first direction D1. The second insulating pattern 140 may be formed of or include at least one of, for example, silicon oxide (SiO), silicon nitride (SiN), silicon oxynitride (SiON), and low-k dielectric materials.

A third insulating pattern 160 may be disposed between the first word line WL1 and the second word line WL2. In an embodiment, a plurality of third insulating patterns 160 may be provided. The third insulating patterns 160 may be extended in the second direction D2 and may be spaced apart from each other in the first direction D1. The first insulating pattern 111 and the second and third insulating patterns 140 and 160 may be alternately arranged in the first direction D1. The third insulating pattern 160 may include at least one of, for example, silicon oxide (SiO), silicon nitride (SiN), silicon oxynitride (SiON), or low-k dielectric materials.

An upper insulating layer 170 may be disposed on the back-gate capping pattern 115, the third insulating pattern 160, the back-gate insulating pattern 113, the semiconductor pattern SP, and the gate insulating pattern Gox.

A storage node contact BC may be disposed to penetrate the upper insulating layer 170. In an embodiment, a plurality of storage node contacts BC may be provided. The storage node contacts BC may be disposed on the first and second vertical portions V1 and V2 of the semiconductor pattern SP, respectively. The storage node contact BC may be formed of and/or may include at least one of doped polysilicon, metallic materials (e.g., aluminum (Al), copper (Cu), titanium (Ti), tantalum (Ta), ruthenium (Ru), tungsten (W), molybdenum (Mo), platinum (Pt), nickel (Ni), cobalt (Co)), conductive metal nitride materials (e.g., titanium nitride (TiN), tantalum nitride (TaN), tungsten nitride (WN), niobium nitride (NbN), titanium aluminide (TiAl), titanium aluminum nitride (TiAlN), titanium silicon nitride (TiSiN), tantalum silicon nitride (TaSiN), ruthenium titanium nitride (RuTiN)), conductive metal silicide materials (e.g., titanium silicide (TiSi₂), tantalum silicide (TaSi), nickel silicide (NiSi), cobalt silicide (CoSi)), or conductive metal oxide materials (e.g., platinum oxide (PtO), iridium oxide (IrOₓ), ruthenium oxide (RuOₓ)), or combinations thereof. However, the present disclosure is not limited to these examples.

Separation insulating layer 171 and landing pads LP may be disposed on the upper insulating layer 170. The landing pads LP may be disposed on the first and second vertical portions V1 and V2 of the semiconductor pattern SP, respectively. The landing pads LP may be in direct contact with the first and second vertical portions V1 and V2 and may be electrically connected to the first and second vertical portions V1 and V2. When viewed in a plan view, the landing pads LP may be spaced apart from each other in the first and second directions D1 and D2 and may be arranged in various shapes (e.g., in matrix, zigzag, and honeycomb shapes). When viewed in a plan view, each of the landing pads LP may have various shapes (e.g., circular, elliptical, rectangular, square, diamond, and hexagonal shapes).

The landing pads LP may be formed of and/or may include at least one of doped polysilicon, metallic materials (e.g., aluminum (Al), copper (Cu), titanium (Ti), tantalum (Ta), ruthenium (Ru), tungsten (W), molybdenum (Mo), platinum (Pt), nickel (Ni), cobalt (Co)), conductive metal nitride materials (e.g., titanium nitride (TiN), tantalum nitride (TaN), tungsten nitride (WN), niobium nitride (NbN), titanium aluminide (TiAl), titanium aluminum nitride (TiAlN), titanium silicon nitride (TiSiN), tantalum silicon nitride (TaSiN), ruthenium titanium nitride (RuTiN)), conductive metal silicide materials (e.g., titanium silicide (TiSi₂), tantalum silicide (TaSi), nickel silicide (NiSi), cobalt silicide (CoSi)), or conductive metal oxide materials (e.g., platinum oxide (PtO), iridium oxide (IrOₓ), ruthenium oxide (RuOₓ)), or combinations thereof. However, the present disclosure is not limited to these examples.

Data storage patterns DSP may be disposed on the landing pads LP, respectively. The data storage patterns DSP may be electrically connected to the first and second vertical portions V1 and V2, respectively, of the semiconductor pattern SP through the landing pads LP.

In an embodiment, the data storage pattern DSP may be a capacitor and may include storage electrodes SE, a plate electrode PE, and a capacitor dielectric layer CIL interposed therebetween. In this case, the storage electrode SE may be in contact with the landing pad LP.

Alternatively or additionally, the data storage pattern DSP may be and/or may include a variable resistance pattern whose resistance may be switched to one of at least two states by an electric pulse applied thereto. For example, the data storage pattern DS may be formed of and/or may include at least one of phase-change materials (whose crystal state may be changed depending on an amount of a current applied thereto), perovskite compounds, transition metal oxides, magnetic materials, ferromagnetic materials, antiferromagnetic materials, or the like.

According to an embodiment, the semiconductor pattern SP may include the first and second vertical portions V1 and V2 and the horizontal portion H connecting the first and second vertical portions V1 and V2 to each other. The bottom surfaces Vb of the first and second vertical portions V1 and V2 may be in contact with the bit line BL, and furthermore, a bottom surface of the horizontal portion H may also be in direct contact with the bit line BL. Thus, a contact area between the bit line BL and the semiconductor pattern SP may be increased, and a resistance therebetween may be lowered. Accordingly, aspects of the present disclosure provide for a semiconductor device with improved electrical and reliability characteristics, when compared to related semiconductor devices.

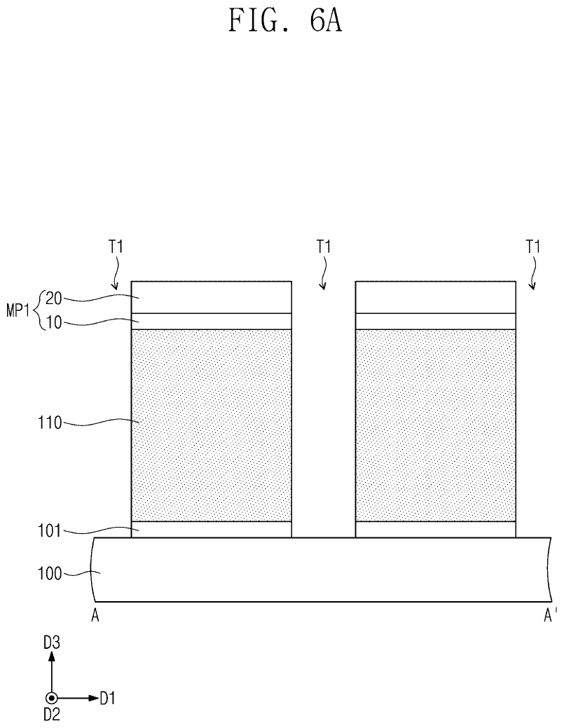

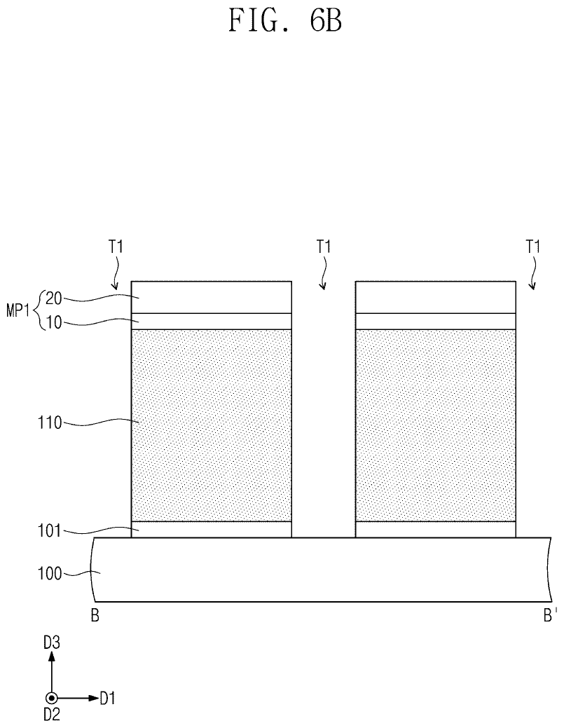

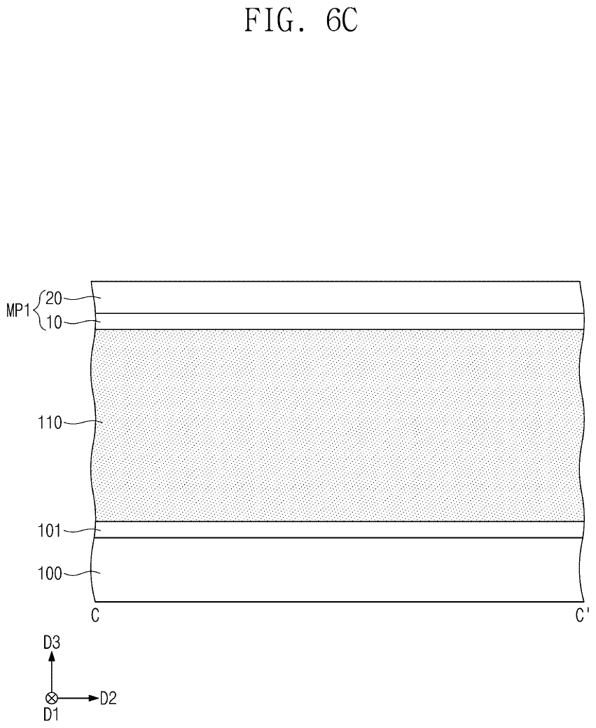

FIGS. 6A to 17C are sectional views illustrating a method of fabricating a semiconductor device, according to an embodiment. That is, FIGS. 6A, 7A, 8A, 9A, 10A, 11A, 12A, 13A, 14A, 15A, 16A, and 17A are sectional views corresponding to the line A-A′ of FIG. 4. FIGS. 6B, 7B, 8B, 9B, 10B, 11B, 12B, 13B, 14B, 15B, 16B, and 17B are sectional views corresponding to the line B-B′ of FIG. 4. FIGS. 6C, 7C, 8C, 9C, 10C, 11C, 12C, 13C, 14C, 15C, 16C, and 17C are sectional views corresponding to the line C-C′ of FIG. 4. Hereinafter, a method of fabricating a semiconductor device, according to an embodiment of the present disclosure is described with reference to FIGS. 4 and 6A to 17C. For the sake of brevity, a previously described element may be identified by the same reference number without repeating an overlapping description thereof.

Referring to FIGS. 4 and 6A to 6C, a substrate structure including a first substrate 100, a buried insulating layer 101, and an active layer 110 may be prepared. The substrate structure may be a silicon-on-insulator (SOI) substrate.

In an embodiment, the first substrate 100 may be a silicon (Si) substrate, a germanium (Ge) substrate, and/or a silicon-germanium (Si—Ge) substrate. However, the present disclosures is not limited to these examples.

The buried insulating layer 101 may be a buried oxide (BOX) layer, which may be formed by a separation-by-implanted oxygen (SIMOX) method and/or by a bonding and layer-transfer method. Alternatively or additionally, the buried insulating layer 101 may be an insulating layer, which may be formed by a chemical vapor deposition method. In an embodiment, the buried insulating layer 101 may include a silicon oxide (SiO) layer, a silicon nitride (SiN) layer, a silicon oxynitride (SiON) layer, and/or a low-k dielectric layer.

The active layer 110 may be a single crystalline semiconductor layer. For example, the active layer 110 may be a single-crystalline silicon (Si) substrate, a single-crystalline germanium (Ge) substrate, and/or a single-crystalline silicon-germanium (Si—Ge) substrate.

A first mask pattern MP1 may be formed on the active layer 110. The first mask pattern MP1 may include a buffer layer 10 and a mask layer 20. The first mask pattern MP1 may be spaced apart from each other in the first direction D1 and may have line-shaped openings extending in the second direction D2.

In an embodiment, first trenches T1 may be formed on the first substrate 100. In an embodiment, the formation of the first trenches T1 may include sequentially etching the active layer 110 and the buried insulating layer 101 using the first mask pattern MP1 as an etch mask. The first trenches T1 may expose the first substrate 100. The first trenches T1 may be spaced apart from each other in the first direction D1.

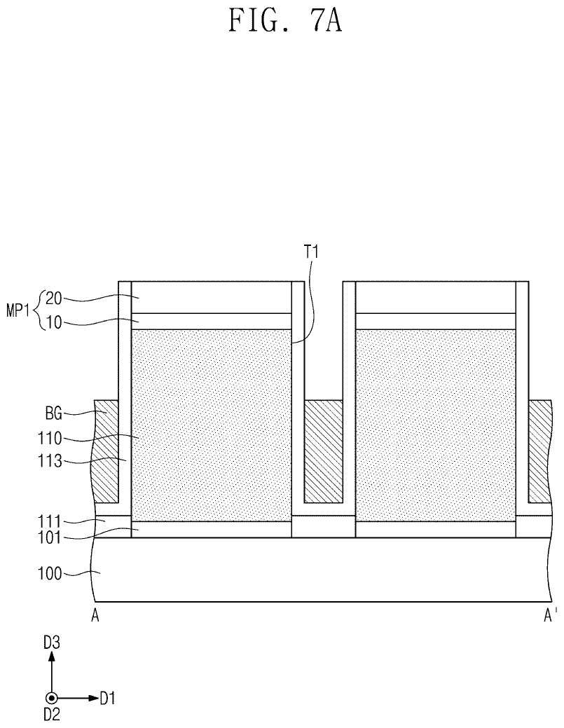

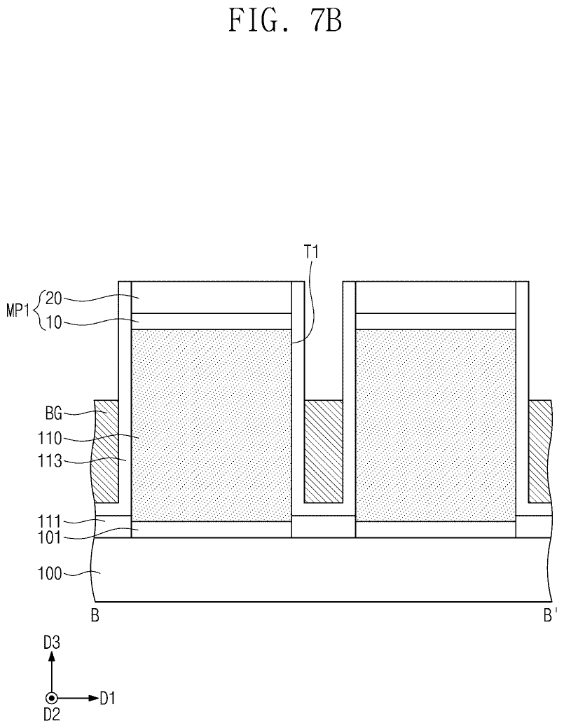

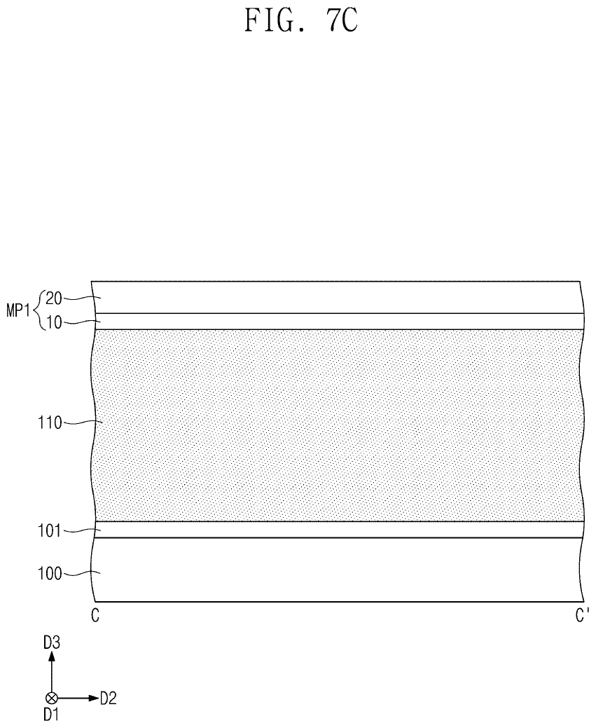

Referring to FIGS. 4 and 7A to 7C, the first insulating patterns 111 may be formed to fill lower portions of the first trenches T1. In an embodiment, the formation of the first insulating patterns 111 may include depositing an insulating material to fill the first trenches T1 and etching the insulating material. Each of the first insulating patterns 111 may expose side surfaces of a corresponding one of the first trenches T1.

After the formation of the first insulating patterns 111, the back-gate insulating patterns 113 and the back-gate electrodes BG may be formed in the first trenches T1. In an embodiment, the formation of the back-gate insulating patterns 113 and the back-gate electrodes BG may include depositing a back-gate insulating layer to conformally cover side surfaces of the first trenches T1, depositing a back-gate conductive layer to fill remaining portions of the first trenches T1 covered with the back-gate insulating layer, and etching the back-gate insulating layer and the back-gate conductive layer. Each of the back-gate insulating patterns 113 may conformally cover a side surface of a corresponding one of the first trenches T1. Each of the back-gate electrodes BG may be formed on a corresponding one of the back-gate insulating patterns 113. The back-gate electrodes BG may be spaced apart from the active layers 110, with the back-gate insulating patterns 113 interposed therebetween.

In an embodiment, the active layers 110 exposed through the side surfaces of the first trenches T1 may be doped with impurities by performing a gas doping (GPD) process or a plasma doping (PLAD) process before the formation of the back-gate insulating patterns 113.

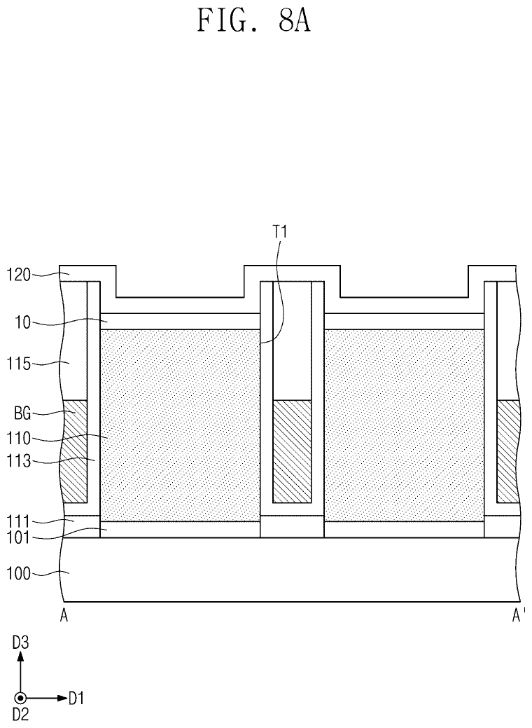

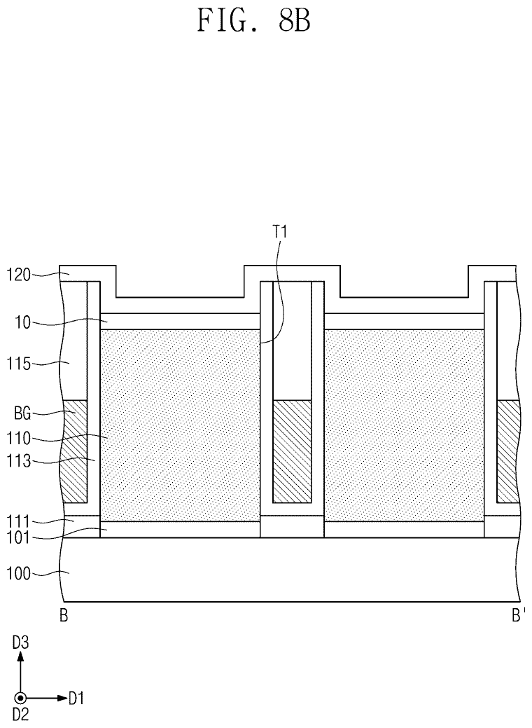

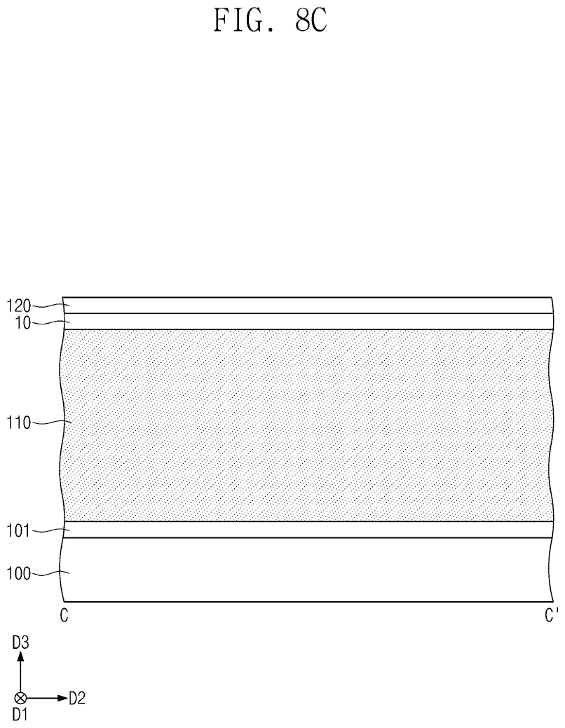

Referring to FIGS. 4 and 8A to 8C, the back-gate capping patterns 115 may be formed in remaining portions of the first trenches T1, in which the back-gate insulating patterns 113 and the back-gate electrodes BG may be formed. In an embodiment, the formation of the back-gate capping patterns 115 may include forming a back-gate capping layer to fill the remaining portions of the first trenches T1 and etching the back-gate capping layer.

The mask layer 20 of the first mask pattern MP1 may be removed, after the formation of the back-gate capping patterns 115. As a result of the removal of the mask layer 20, the back-gate capping patterns 115 and the back-gate insulating patterns 113 may protrude from a top surface of the buffer layer 10 in the vertical direction D3.

In an embodiment, a spacer layer 120 may be formed on the first substrate 100. The spacer layer 120 may conformally cover side surfaces and top surfaces of the back-gate insulating patterns 113, top surfaces of the back-gate capping patterns 115, and the top surface of the buffer layer 10. The thickness of the channel regions of the vertical channel transistors may be determined depending on a deposition thickness of the spacer layer 120. The spacer layer 120 may be formed of an insulating material. For example, the spacer layer 120 may be formed of or include at least one of silicon oxide (SiO), silicon oxynitride (SiON), silicon nitride (SiN), silicon carbide (SiC), silicon carbon nitride (SiCN), or combinations thereof. However, the present disclosure is not limited to these examples.

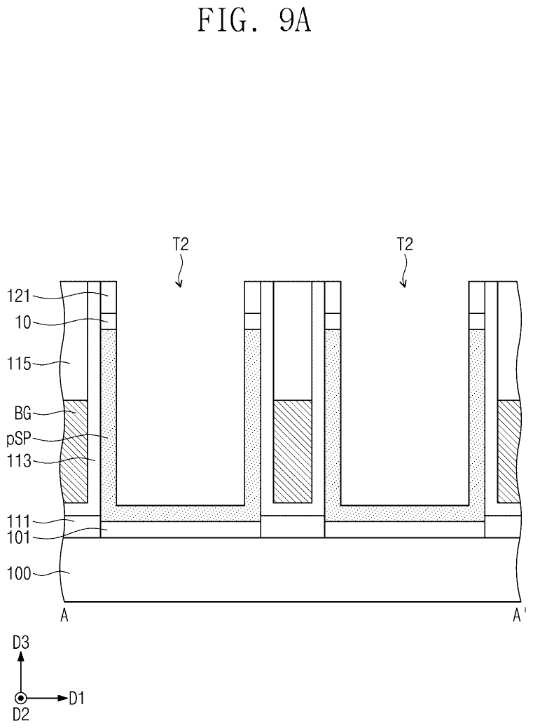

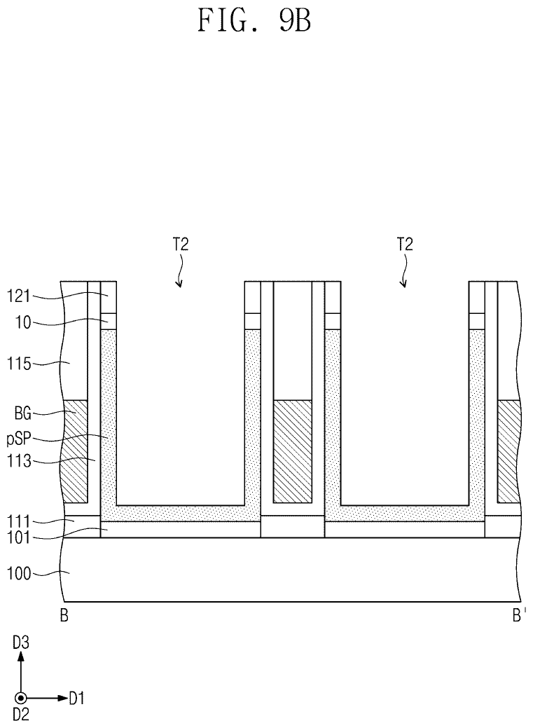

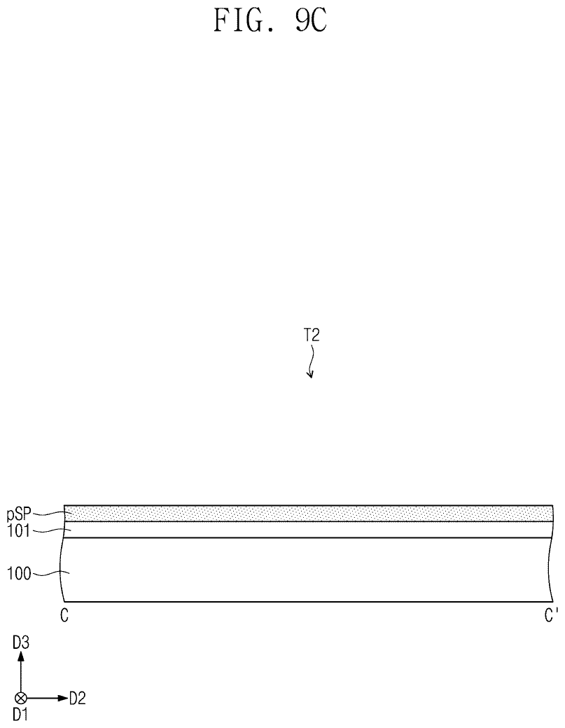

Referring to FIGS. 4 and 9A to 9C, spacer patterns 121 may be formed on side surfaces of the back-gate insulating patterns 113. The spacer patterns 121 may be formed by performing an anisotropic etching process on the spacer layer 120.

In an embodiment, second trenches T2 and preliminary semiconductor patterns pSP may be formed. In an embodiment, the formation of the second trenches T2 may include etching the buffer layer 10 and the active layer 110 using the spacer patterns 121 as an etch mask. In an embodiment, a portion of the buffer layer 10, which may be exposed by the spacer patterns 121, may be etched, and only a portion of the active layer 110, which may be exposed as a result of the etching, may be etched. The second trenches T2 may be formed without exposing the buried insulating layer 101. Each of the preliminary semiconductor patterns pSP may include vertical portions, which may be spaced apart from each other in the first direction D1, and a horizontal portion, which may be provided between the vertical portions to connect the vertical portions to each other.

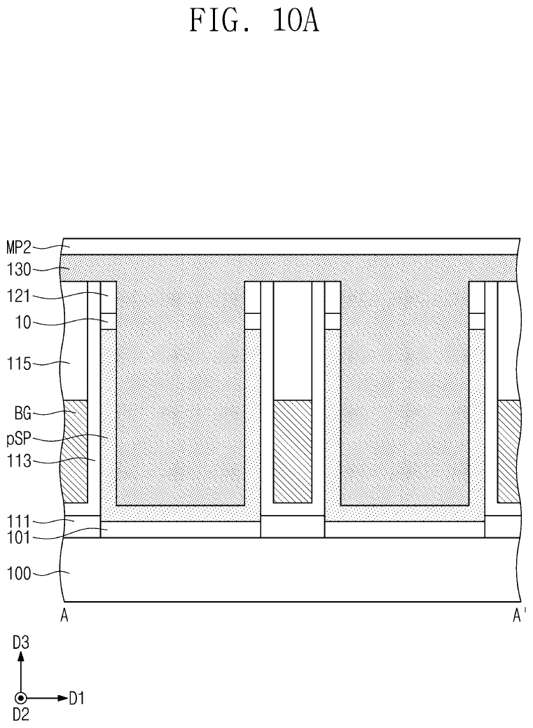

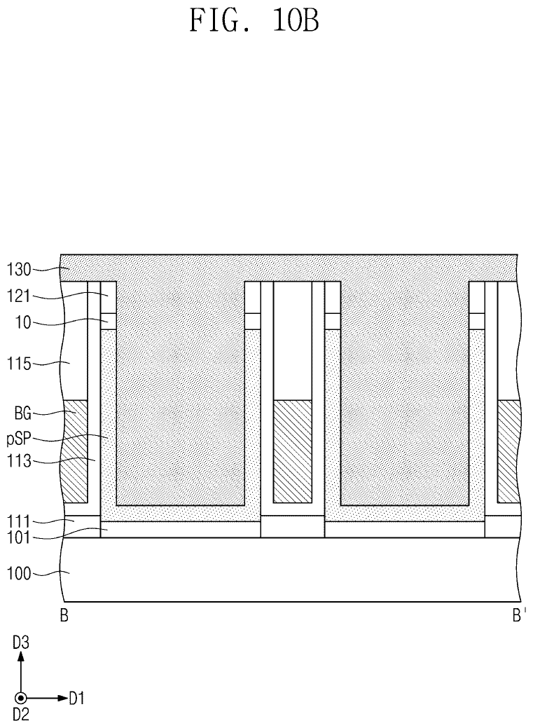

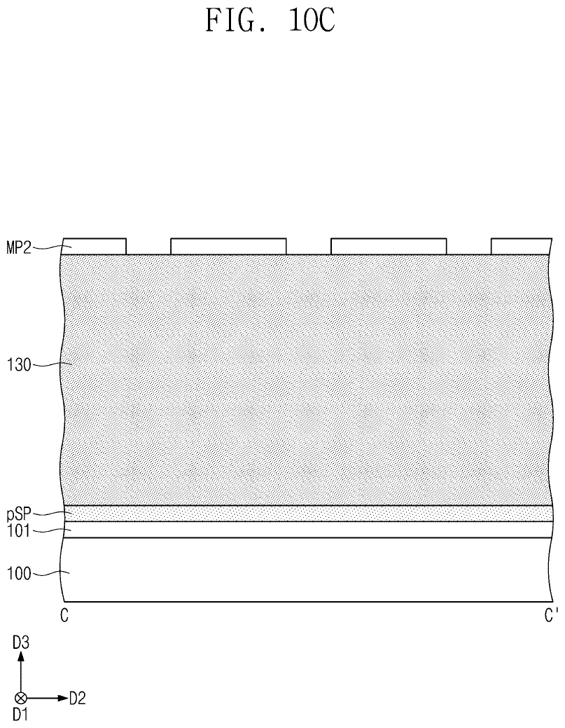

Referring to FIGS. 4 and 10A to 10C, a first sacrificial layer 130 may be formed on the first substrate 100. The first sacrificial layer 130 may be formed to fill the second trenches T2 and may be extended to cover top surfaces of the spacer patterns 121, the back-gate capping patterns 115, and the back-gate insulating patterns 113. In an embodiment, the formation of the first sacrificial layer 130 may include forming a sacrificial layer to cover the first substrate 100 and planarizing the sacrificial layer. The planarization may be performed using, for example, a chemical mechanical polishing (CMP) process, an etch-back process, or the like.

A second mask pattern MP2 may be formed on the first sacrificial layer 130. The second mask pattern MP2 may be line-shaped patterns, which may be extended in the first direction D1 and are spaced apart from each other in the second direction D2. The second mask pattern MP2 may include a material having an etch selectivity with respect to the first sacrificial layer 130.

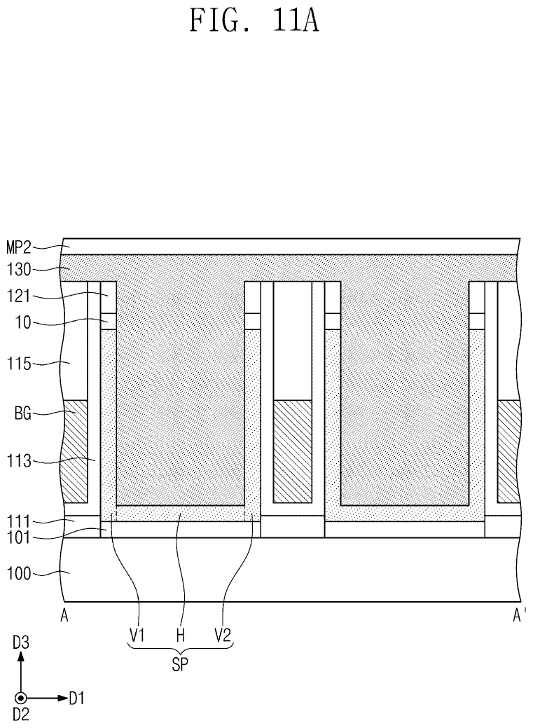

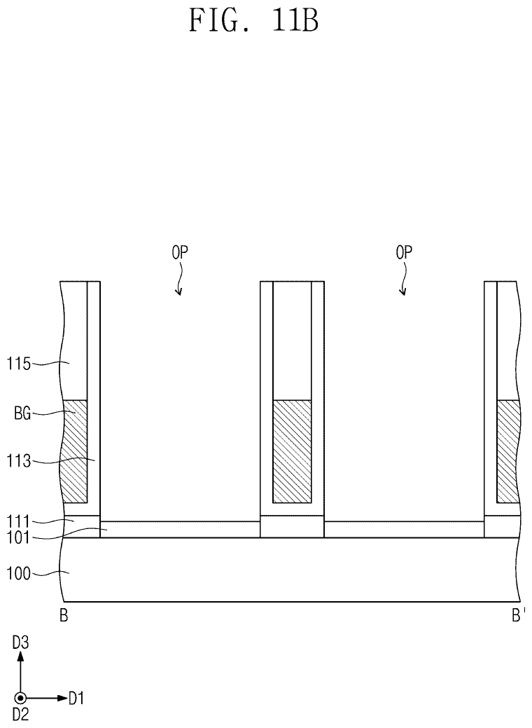

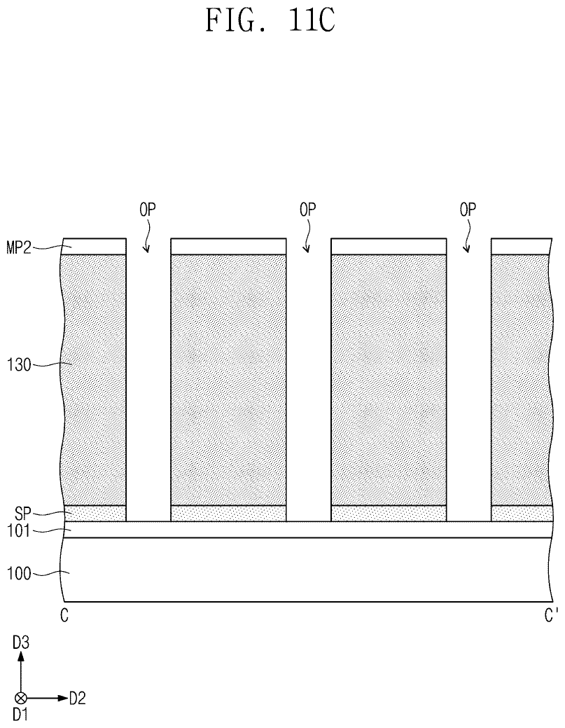

Referring to FIGS. 4 and 11A to 11C, openings OP may be formed to extend in the first direction D1 and may be spaced apart from each other in the second direction D2. In an embodiment, the formation of the openings OP may include etching the first sacrificial layer 130, the spacer patterns 121, the buffer layer 10, and the preliminary semiconductor patterns pSP using the second mask pattern MP2 as an etch mask. The openings OP may be formed to expose the buried insulating layer 101. Thus, the semiconductor patterns SP, which may be spaced apart from each other in the first and second directions D1 and D2, may be formed. The semiconductor patterns SP may be remaining portions of the preliminary semiconductor patterns pSP, which may be etched by the etching process.

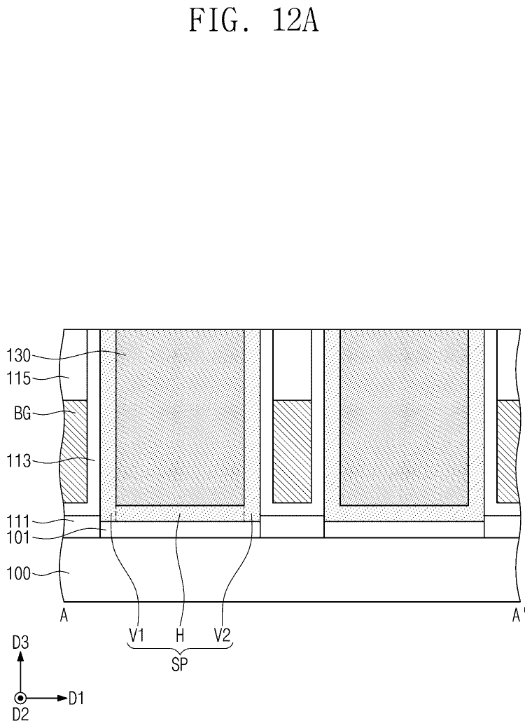

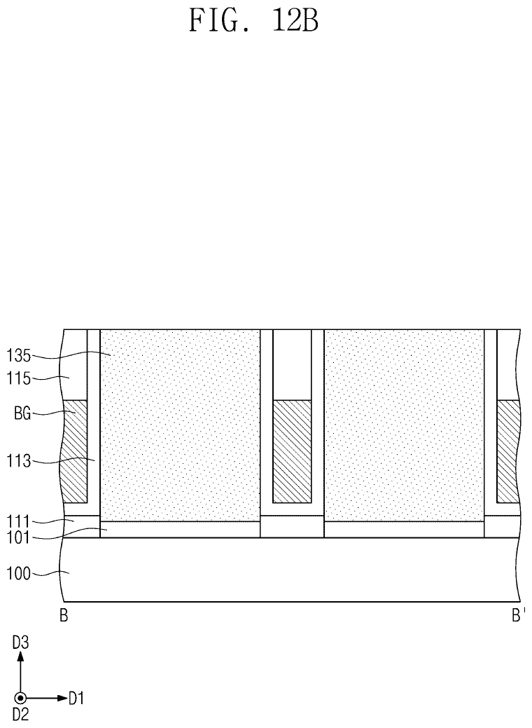

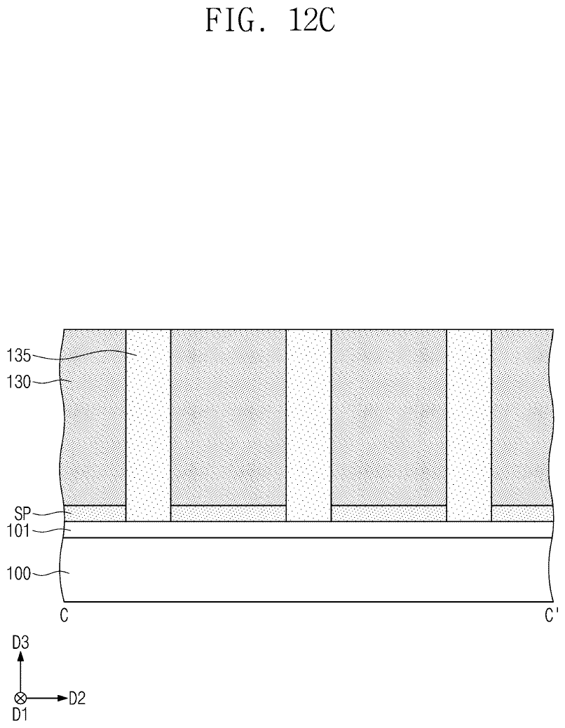

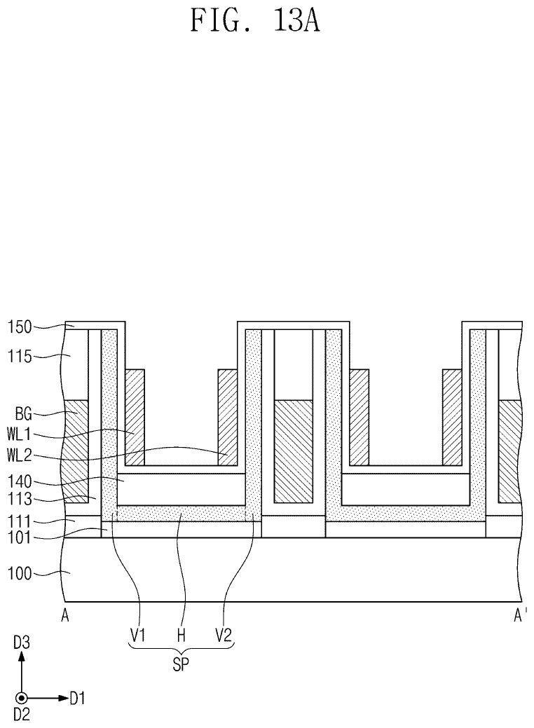

Referring to FIGS. 4 and 12A to 12C, the openings OP may be filled with a second sacrificial layer 135. The second sacrificial layer 135 may include the same material as the first sacrificial layer 130. The second mask pattern MP2 may be removed, after the formation of the second sacrificial layer 135. After the removal of the second mask pattern MP2, a planarization process may be performed to expose top surfaces of the first and second vertical portions V1 and V2 of the semiconductor patterns SP. The spacer patterns 121 and the remaining portions of the buffer layer 10 may be removed by the planarization process.

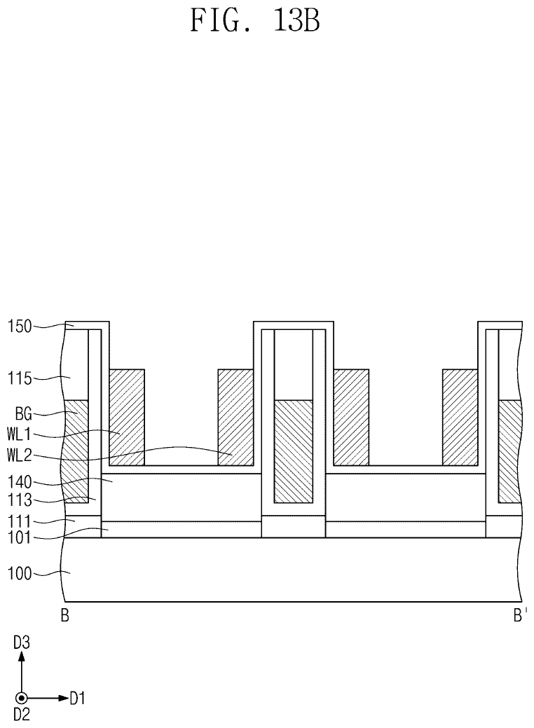

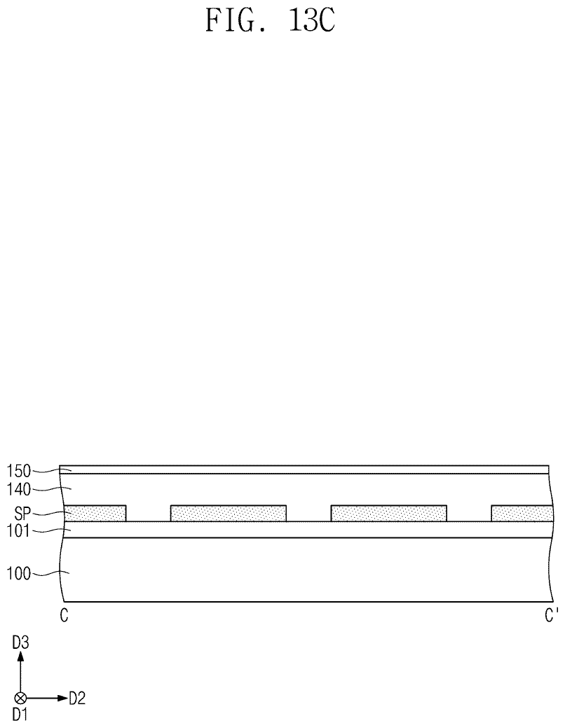

Referring to FIGS. 4 and 13A to 13C, the first and second sacrificial layers 130 and 135 may be removed. Thus, the inner side surfaces of the semiconductor patterns SP may be re-exposed. Additionally, the buried insulating layer 101 may be re-exposed between the back-gate insulating patterns 113.

In an embodiment, the second insulating patterns 140 may be formed on the horizontal portions H of the semiconductor patterns SP and on the buried insulating layer 101 between the back-gate insulating patterns 113. The second insulating patterns 140 may be extended in the second direction D2 and may be spaced apart from each other in the first direction D1. The first insulating patterns 111 and the second insulating patterns 140 may be alternately arranged in the first direction D1.

A gate insulating layer 150 may be formed on the first substrate 100. The gate insulating layer 150 may conformally cover the side surfaces of the vertical portions V1 and V2 of the semiconductor patterns SP and the top surfaces of the second insulating patterns 140 on the semiconductor patterns SP. The gate insulating layer 150 may be extended to a region on the second insulating patterns 140 between the side surfaces of the back-gate insulating patterns 113. In addition, the gate insulating layer 150 may be extended to a region on the top surfaces of the back-gate capping patterns 115.

The word lines WL1 and WL2 may be formed on each of the semiconductor patterns SP. For example, first and second word lines WL1 and WL2 may be formed on the horizontal portion H to face inner side surfaces of the first and second vertical portions V1 and V2 of each of the semiconductor patterns SP. The word lines WL1 and WL2 may be spaced apart from the semiconductor pattern SP, with the gate insulating layer 150 interposed therebetween. In an embodiment, the formation of the word lines WL1 and WL2 may include forming a word line layer on the gate insulating layer 150 and performing an etching process on the word line layer. Top surfaces of the word lines WL1 and WL2 may be located at a level lower than the top surfaces of the first and second vertical portions V1 and V2.

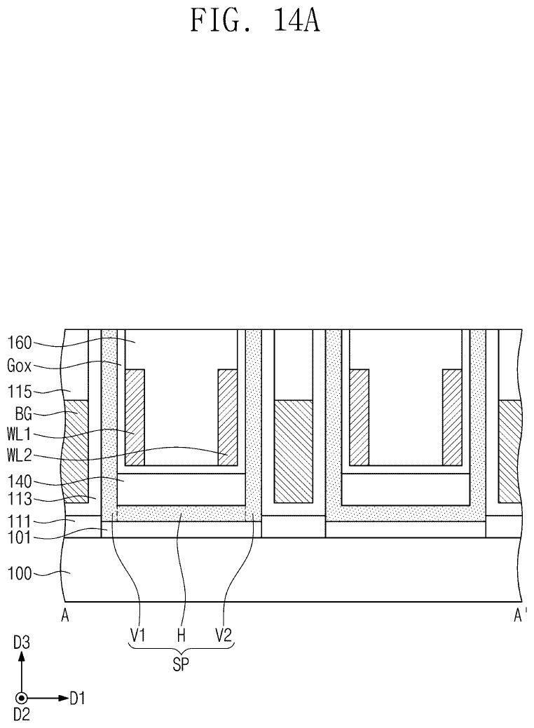

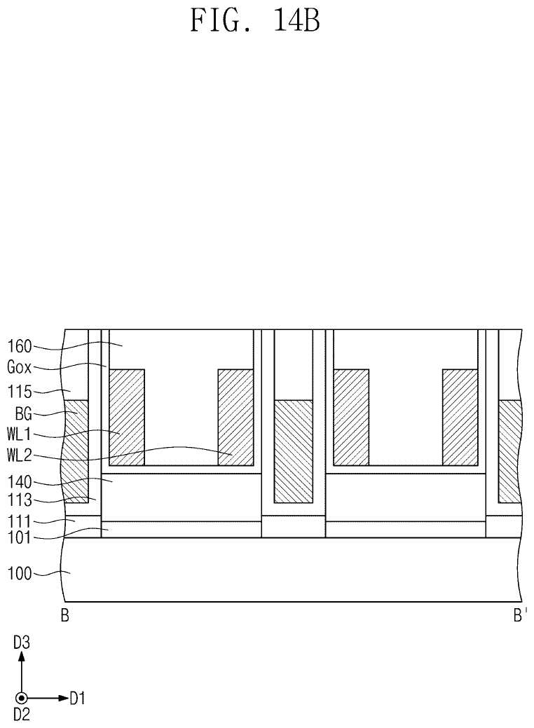

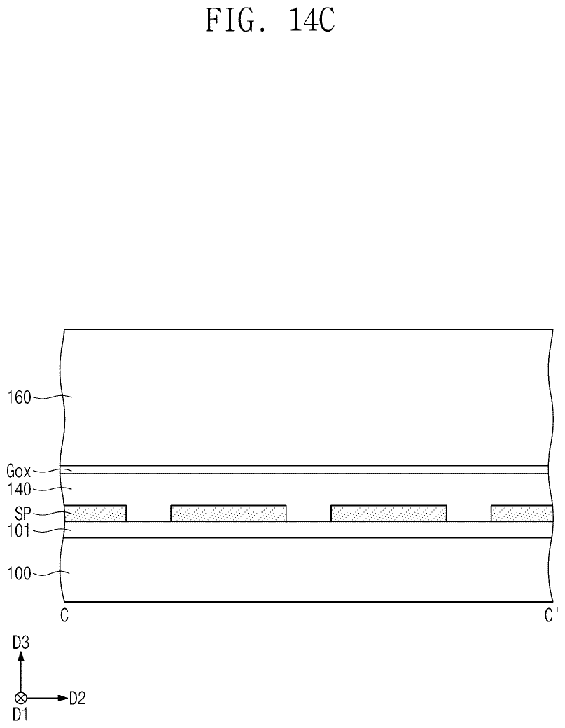

Referring to FIGS. 4 and 14A to 14C, the third insulating patterns 160 may be formed to fill a region between the first and second word lines WL1 and WL2. In addition, gate insulating patterns Gox may be formed. In an embodiment, the formation of the third insulating patterns 160 and the gate insulating patterns Gox may include forming a preliminary third insulating layer and planarizing the gate insulating layer 150 and the preliminary third insulating layer to expose the top surfaces of the back-gate capping patterns 115.

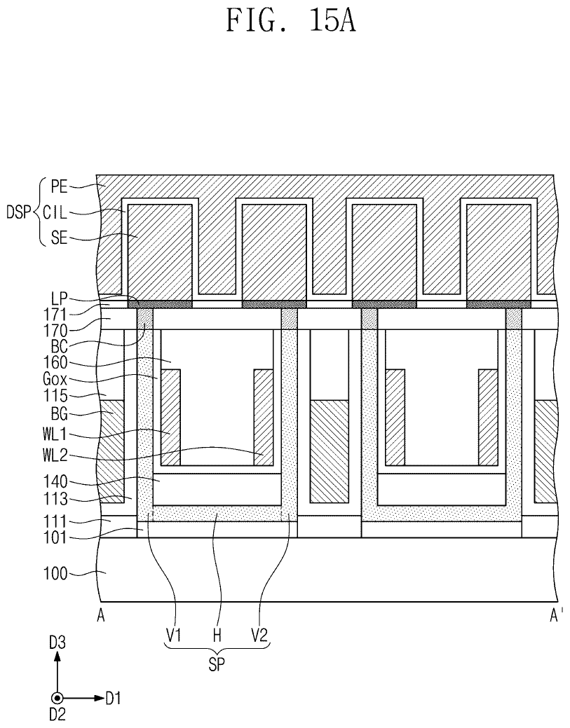

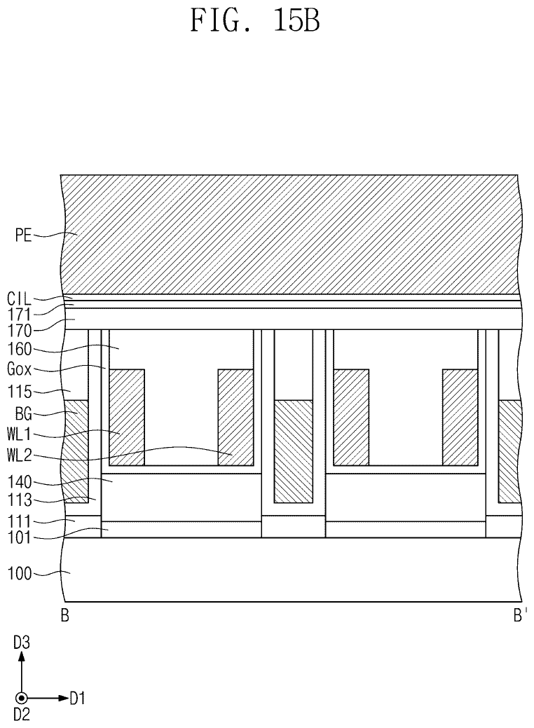

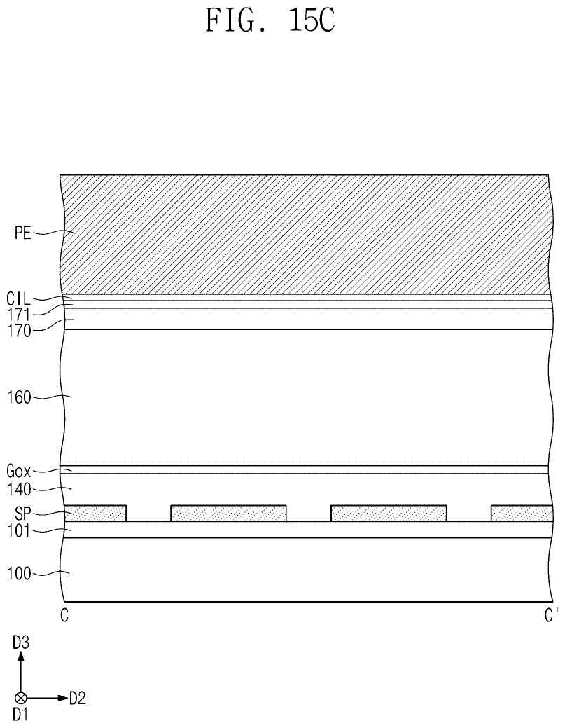

Referring to FIGS. 4 and 15A to 15C, the upper insulating layer 170 may be formed on the first substrate 100. In an embodiment, the storage node contacts BC may be formed to penetrate the upper insulating layer 170 and may be respectively connected to the first and second vertical portions V1 and V2 of the semiconductor patterns SP. In an embodiment, the formation of the storage node contacts BC may include etching the upper insulating layer 170 to form holes exposing the first and second vertical portions V1 and V2, depositing a conductive layer to fill the holes, and planarizing the conductive layer to expose a top surface of the upper insulating layer 170.

In an embodiment, the separation insulating layer 171 may be formed on the upper insulating layer 170. The landing pads LP, which are respectively connected to the storage node contacts BC, may be formed to penetrate the separation insulating layer 171. In an embodiment, the formation of the landing pads LP may include etching the separation insulating layer 171 to form holes exposing the storage node contacts BC, depositing a conductive layer to fill the holes, and planarizing the conductive layer to expose a top surface of the separation insulating layer 171.

The data storage patterns DSP may be formed on and connected to the landing pads LP, respectively. For example, the storage electrodes SE may be formed on the landing pads LP, respectively, and the capacitor dielectric layer CIL may be formed to conformally cover the storage electrodes SE. In an embodiment, the plate electrode PE may be formed on the capacitor dielectric layer CIL.

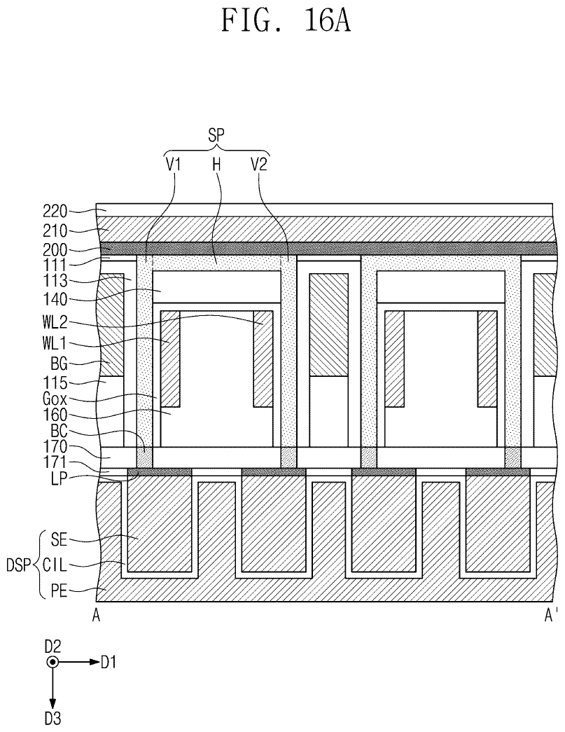

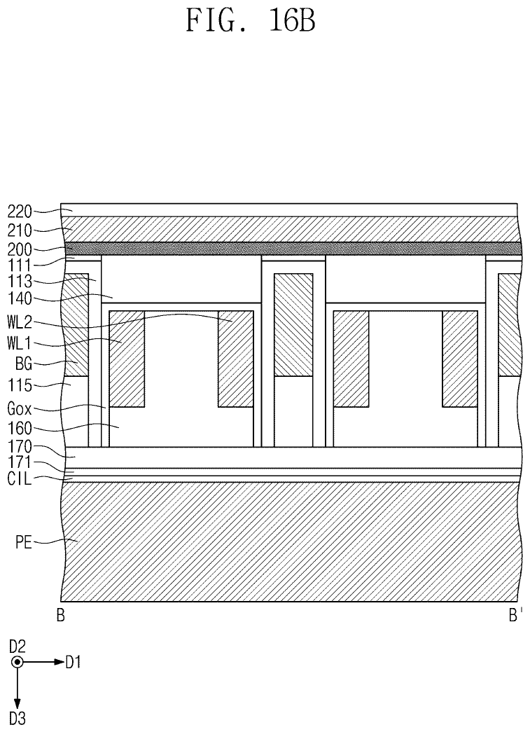

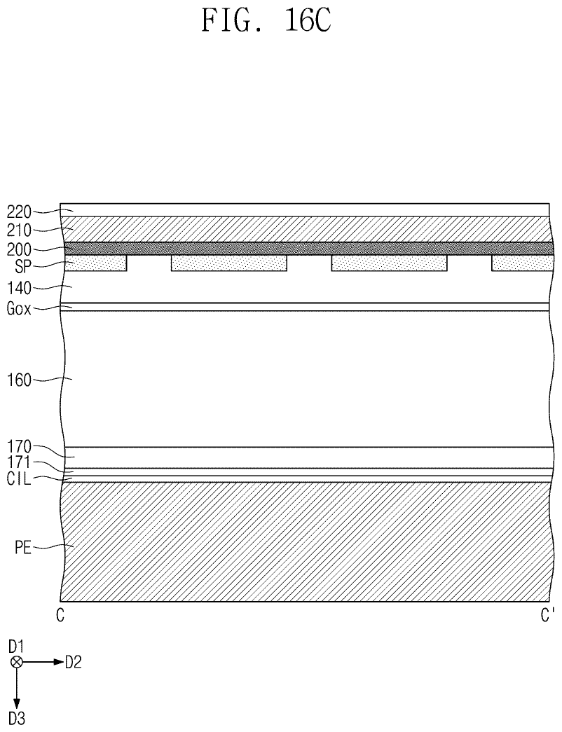

Referring to FIGS. 4 and 16A to 16C, the semiconductor device in fabrication may be inverted, after the formation of the data storage patterns DSP. That is, the inversion may be performed in such a way that the data storage patterns DSP may be placed at a lower level. In an embodiment, the first substrate 100 may be removed. After the removal of the first substrate 100, the buried insulating layer 101 and portions of the first insulating patterns 111 may be additionally removed. In an embodiment, the removal of the first substrate 100, the buried insulating layer 101, and the portions of the first insulating patterns 111 may include planarizing the first substrate 100, the buried insulating layer 101, and the portions of the first insulating patterns 111 to expose the horizontal portions H of the semiconductor patterns SP. In an embodiment, the planarization may be achieved through a chemical mechanical polishing (CMP) process.

In an embodiment, a poly-silicon layer 200, a metal layer 210, and a hard mask layer 220 may be sequentially formed on the semiconductor patterns SP and remaining portions of the first insulating patterns 111.

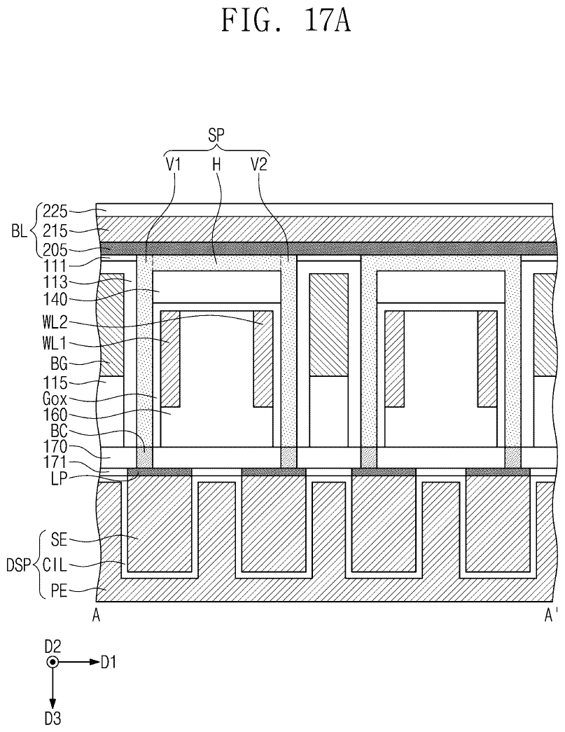

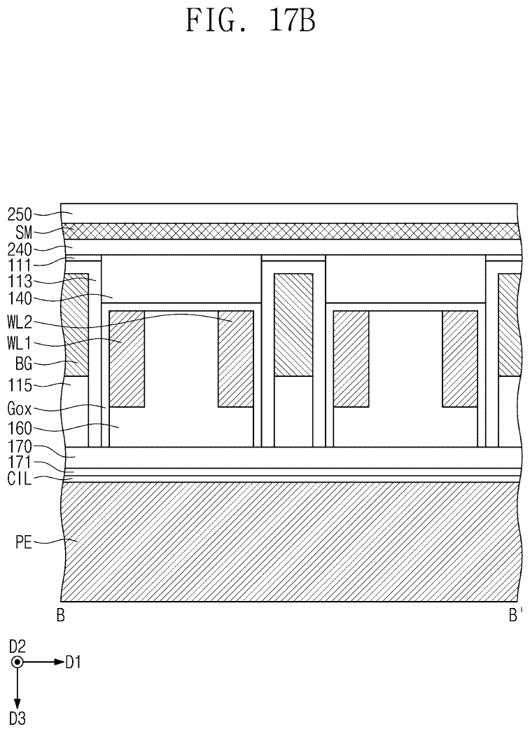

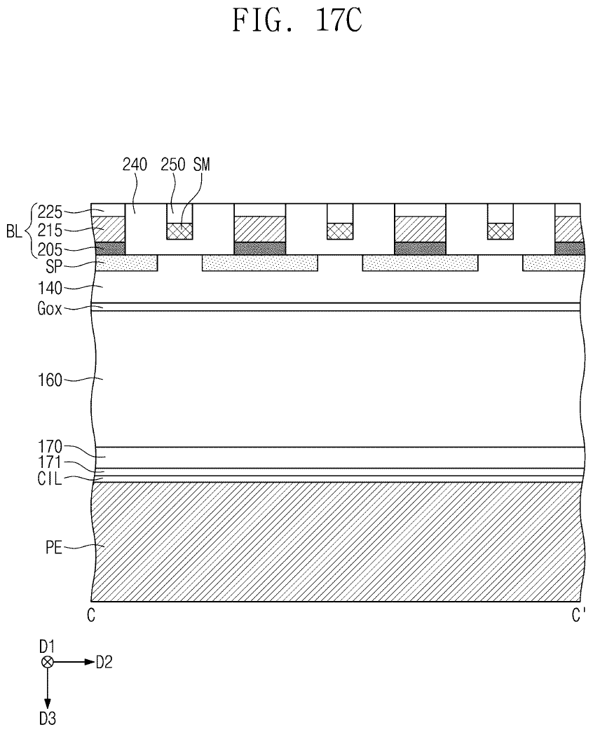

Referring to FIGS. 4 and 17A to 17C, the bit lines BL may be formed. Each of the bit lines BL may include the polysilicon pattern 205, the metal pattern 215, and the hard mask pattern 225. In an embodiment, the formation of the bit lines BL may include forming a mask pattern on the hard mask layer 220, sequentially etching the hard mask layer 220, the metal layer 210, and the poly-silicon layer 200 using the mask pattern as an etch mask, and removing the mask pattern.

After the formation of the bit lines BL, the first insulating layer 240, the shielding structures SM, and the second insulating layer 250 may be formed between the bit lines BL, which may be spaced apart from each other in the second direction D2. In an embodiment, the formation of the first insulating layer 240, the shielding structures SM, and the second insulating layer 250 may include forming a preliminary first insulating layer on the semiconductor device in fabrication, depositing the shielding structures SM on a region defined by the preliminary first insulating layer, forming a preliminary second insulating layer on the semiconductor device in fabrication, and planarizing the preliminary second insulating layer and the preliminary first insulating layer to expose a top surface of the hard mask pattern 225.

Referring back to FIGS. 4 and 5A to 5C, the substrate 300 may be bonded to the semiconductor device in fabrication. After the bonding of the substrate 300, the semiconductor device in fabrication may be inverted. That is, the inverting of the semiconductor device in fabrication may be performed in such a way that the substrate 300 may be placed at a lower level.

FIG. 18 is a sectional view illustrating a semiconductor device, according to an embodiment. For the sake of brevity, a previously described element may be identified by the same reference number without repeating an overlapping description thereof.

Referring to FIG. 18, the top surface of the bit line BL may have an uneven structure. A top surface of a portion of the bit line BL, which may be vertically overlapped with the semiconductor pattern SP, may be placed at a height lower than the uppermost surface BLa of the bit line BL. That is, the top surface of the portion of the bit line BL below the semiconductor pattern SP may be placed at the height lower than the uppermost surface BLa of the bit line BL. For example, the bottom surfaces Vb of the first and second vertical portions V1 and V2 of the semiconductor pattern SP and the bottom surface Hb of the horizontal portion H may be placed at the height lower than the uppermost surface BLa of the bit line BL. In an embodiment, the uppermost surface BLa of the bit line BL may be provided in a region that is not overlapped with the semiconductor pattern SP when viewed in a plan view.

Since the bit line BL has the uneven top surface, a portion of the semiconductor pattern SP may be buried in an upper portion of the bit line BL. In an embodiment, at least a portion of the horizontal portion H of the semiconductor pattern SP may be buried in the upper portion of the bit line BL.

According to an embodiment, a contact area between the bit line BL and the semiconductor pattern SP may be increased, and thereby provide a potentially lower resistance therebetween. In addition, according to the embodiment of FIG. 18, the contact area between the bit line BL and the semiconductor pattern SP may be further increased. Accordingly, aspects of the present disclosure may provide a semiconductor device with improved electrical and/or reliability characteristics, when compared with a related semiconductor device.

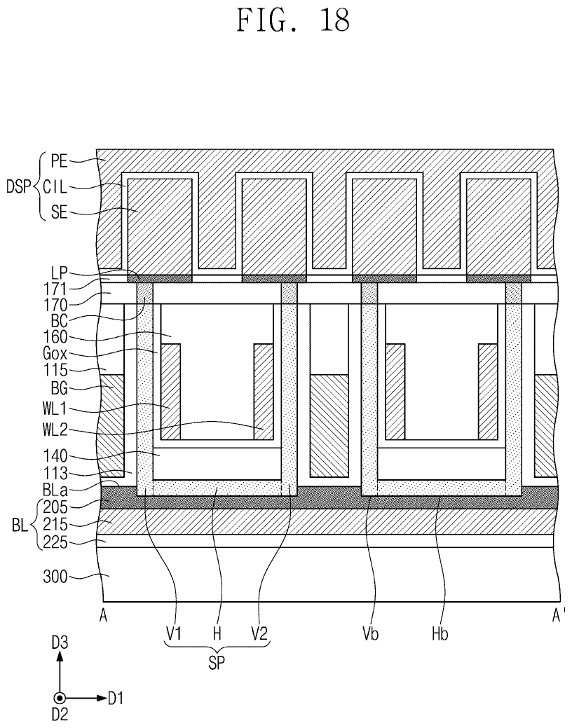

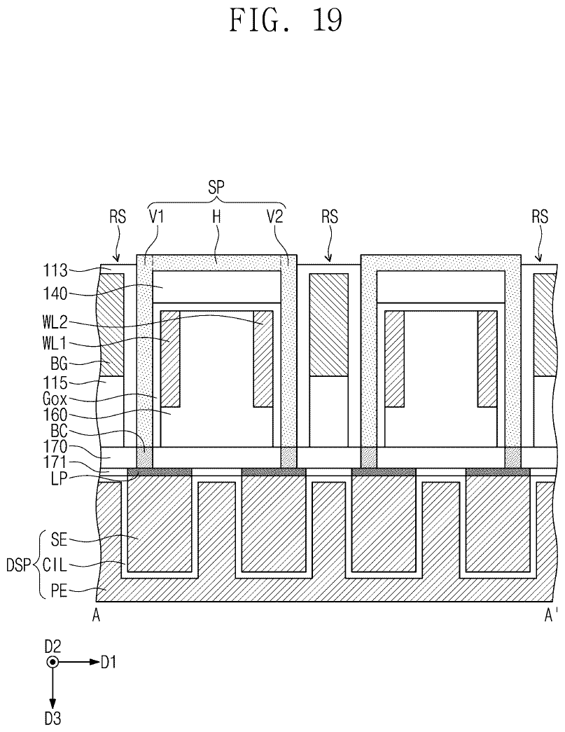

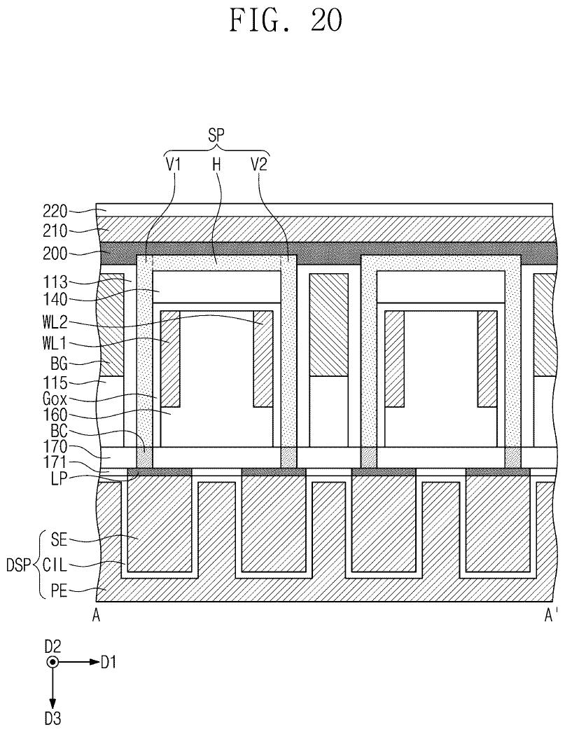

FIGS. 19 and 20 are sectional views corresponding to the line A-A′ of FIG. 4 that illustrate a method of fabricating a semiconductor device, according to an embodiment. For example, FIGS. 19 and 20 illustrate a method of fabricating the semiconductor device of FIG. 18. For the sake of brevity, a previously described element may be identified by the same reference number without repeating an overlapping description thereof.

Referring to FIGS. 4 and 19, the fabrication of the semiconductor device may be substantially similar and/or the same as that in the embodiments described with reference to FIGS. 6A to 15C. In an embodiment, the semiconductor device in fabrication may be inverted. That is, the inversion may be performed in such a way that the data storage patterns DSP are placed at a lower level.

In an embodiment, the first substrate 100, the buried insulating layer 101, and the first insulating patterns 111 may be removed. In an embodiment, the removal of the first substrate 100 and the buried insulating layer 101 may include planarizing the first substrate 100 and the buried insulating layer 101, and portions of the first insulating patterns 111 to expose the horizontal portions H of the semiconductor patterns SP. In addition, remaining portions of the first insulating patterns 111 may be further removed to form recesses RS. The recesses RS may be formed to expose the back-gate insulating patterns 113.

Referring to FIGS. 4 and 20, the poly-silicon layer 200, the metal layer 210, and the hard mask layer 220 may be sequentially stacked on the semiconductor patterns SP and the back-gate insulating patterns 113. The poly-silicon layer 200 may be formed to cover the back-gate insulating pattern 113, between the semiconductor patterns SP which are adjacent to each other in the first direction D1.

Referring back to FIGS. 4 and 18, the bit lines BL may be formed. The formation of the bit lines BL may be formed by a substantially similar and/or the same process as the process described with reference to FIGS. 17A to 17C, and subsequent processes may also be performed.

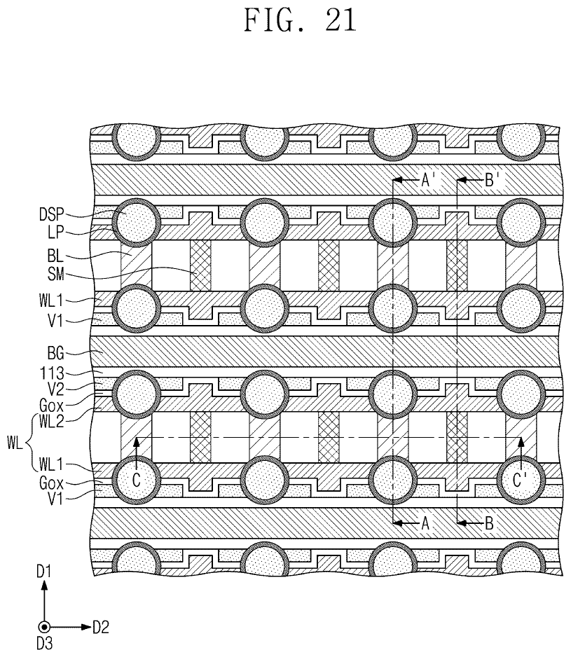

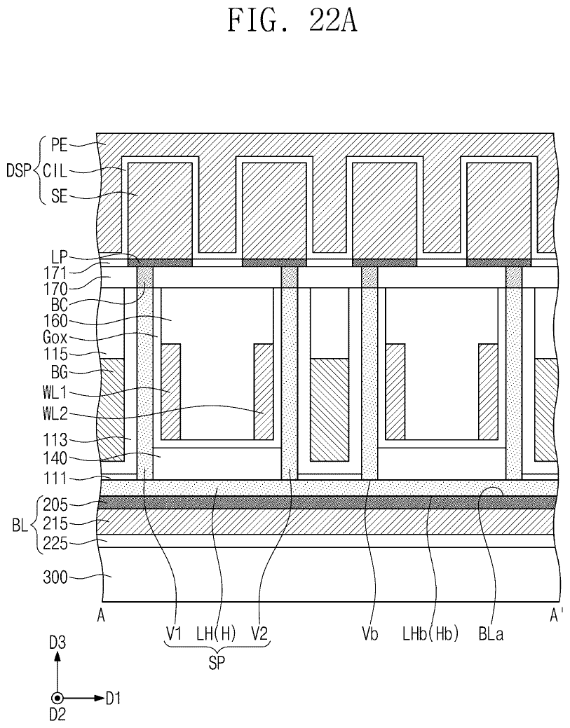

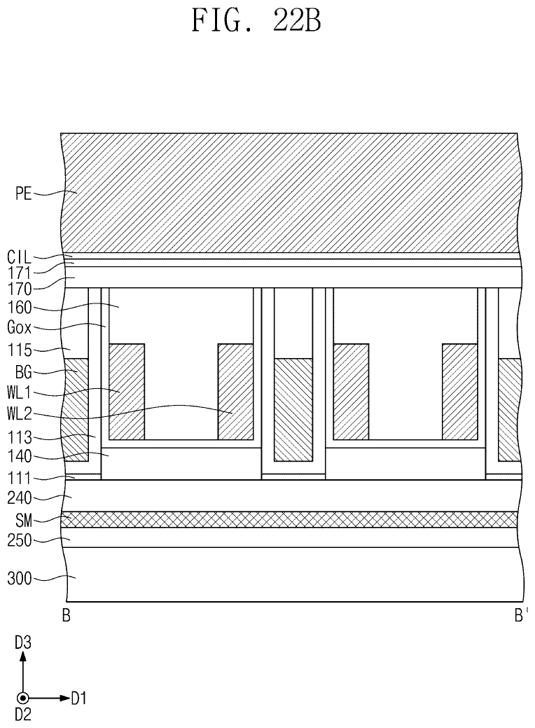

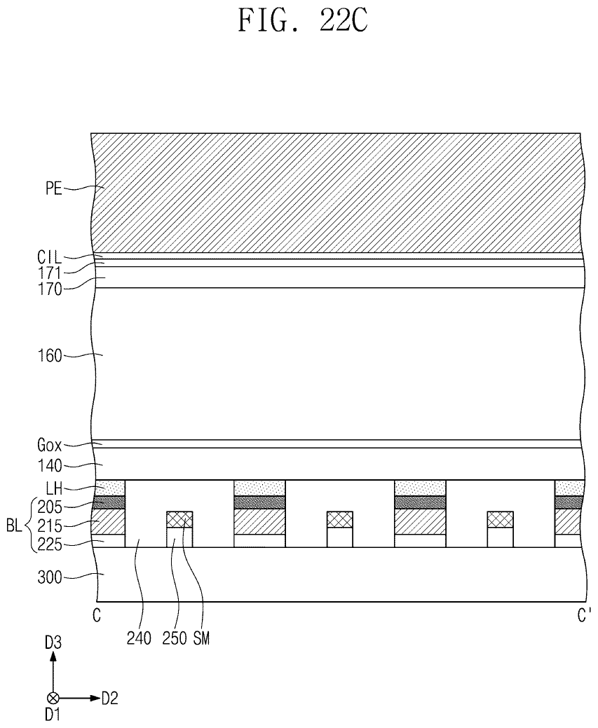

FIG. 21 is a plan view illustrating a semiconductor device, according to an embodiment. FIGS. 22A, 22B, and 22C are sectional views, which are taken along lines A-A′, B-B′, and C-C′ of FIG. 21 to illustrate a semiconductor device according to an embodiment. For the sake of brevity, a previously described element may be identified by the same reference number without repeating an overlapping description thereof.

Referring to FIGS. 21 and 22A to 22C, the semiconductor patterns SP may be disposed on the bit line BL extending in the first direction D1. The semiconductor patterns SP may be spaced apart from each other in the first direction D1, on the bit line BL. Each of the semiconductor patterns SP may include the first vertical portion V1 and the second vertical portion V2, which may be spaced apart from each other in the first direction D1. In addition, each of the semiconductor patterns SP may include the horizontal portion H, which may be provided below the first and second vertical portions V1 and V2 and may connect the first and second vertical portions V1 and V2 to each other. The horizontal portion H may be a line-shaped pattern, which may extend in the first direction D1 and may be used to connect the first and second vertical portions V1 and V2 arranged in the first direction D1. The horizontal portions H of each of the semiconductor patterns SP may be extended into regions between the back-gate electrodes BG and the bit line BL adjacent thereto. That is, the horizontal portions H of each of the semiconductor patterns SP may be extended toward each other in the first direction D1 to form a single object. The horizontal portions H, which may form the single object, may be referred to as a line horizontal portion LH.

A bottom surface LHb of the line horizontal portion LH and the uppermost surface BLa of the bit line BL may be in direct contact with each other and may be located at the same height. The bottom surfaces Vb of the first and second vertical portions V1 and V2 may be located at a height that is higher than the bottom surface of the line horizontal portion LH and the uppermost surface BLa of the bit line BL.

A width of the line horizontal portion LH in the second direction D2 may be equal to a width of the bit line BL in the second direction D2. The width of the line horizontal portion LH in the second direction D2 may be smaller than a width of the first and second vertical portions V1 and V2 in the second direction D2. When viewed in a plan view, the line horizontal portion LH may be vertically overlapped with the bit line BL.

According to an embodiment, a contact area between the bit line BL and the semiconductor pattern SP may be increased, and thereby may provide a lower resistance therebetween. In addition, according to the embodiment of FIGS. 21 and 22A to 22C, the horizontal portion H of the semiconductor pattern SP may be extended to a region below the back-gate electrodes BG, and thus, the contact area between the bit line BL and the semiconductor pattern SP may be further increased. Accordingly, aspects of the present disclosure may provide a semiconductor device with potentially improved electrical and/or reliability characteristics, when compared to a related semiconductor device.

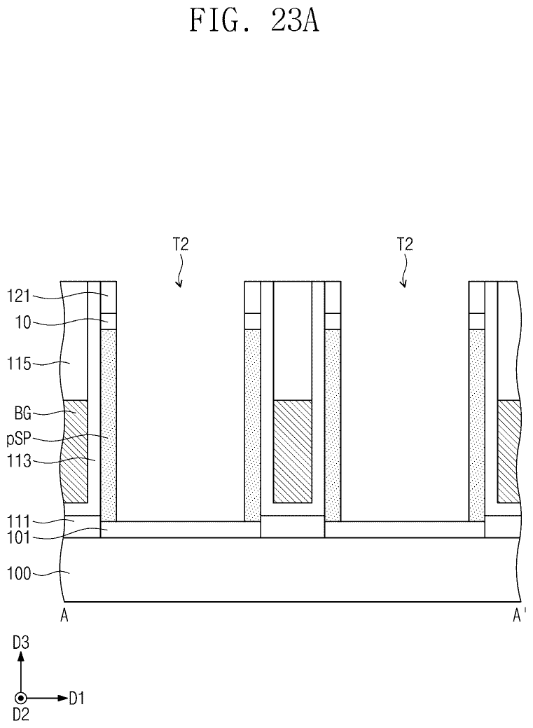

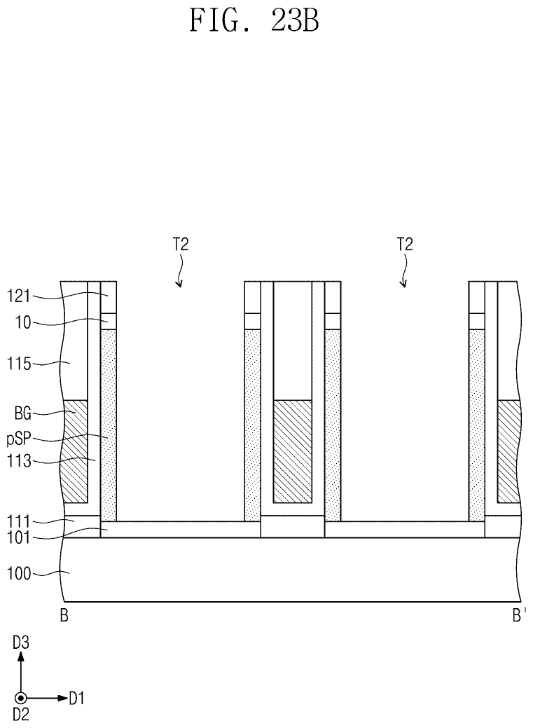

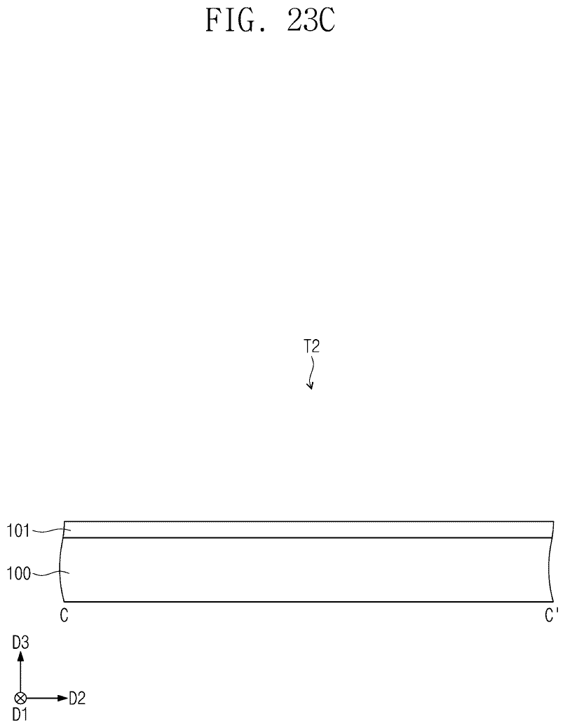

FIGS. 23A to 25C are sectional views illustrating a method of fabricating a semiconductor device, according to an embodiment. That is, FIGS. 23A to 25C illustrate a method of fabricating the semiconductor device of FIGS. 21 and 22A to 22C. FIGS. 23A, 24A, and 25A are sectional views corresponding to a line A-A′ of FIG. 21, FIGS. 23B, 24B, and 25B are sectional views corresponding to a line B-B′ of FIG. 21, and FIGS. 23C, 24C, and 25C are sectional views corresponding to a line C-C′ of FIG. 21. For the sake of brevity, a previously described element may be identified by the same reference number without repeating an overlapping description thereof.

Referring to FIGS. 21 and 23A to 23C, the fabrication of the semiconductor device may be substantially similar and/or the same as the fabrication described with reference to FIGS. 6A to 8C. In an embodiment, the second trenches T2 may be formed. The second trenches T2 may be formed by etching the active layer 110 and may be formed to expose the buried insulating layer 101. Each of the preliminary semiconductor patterns pSP may include vertical portions, which may be spaced apart from each other in the first direction D1.

The fabrication process described with reference to FIGS. 10A to 15C may be further performed in a substantially similar and/or the same manner.

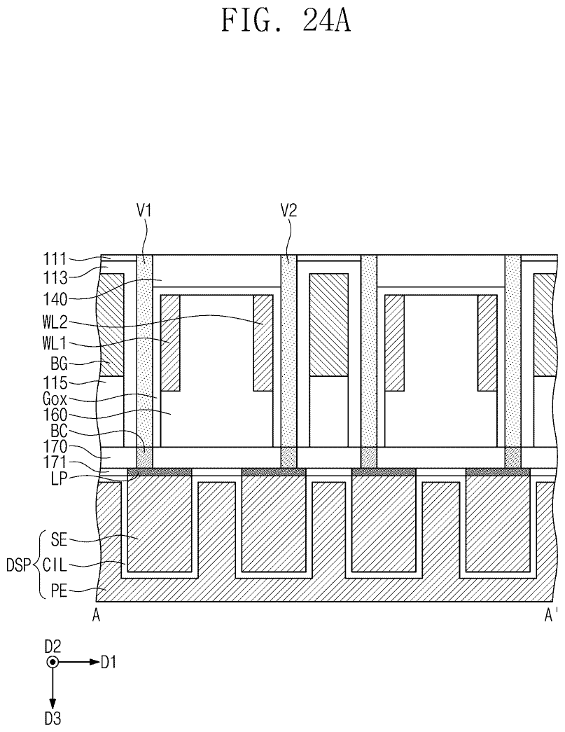

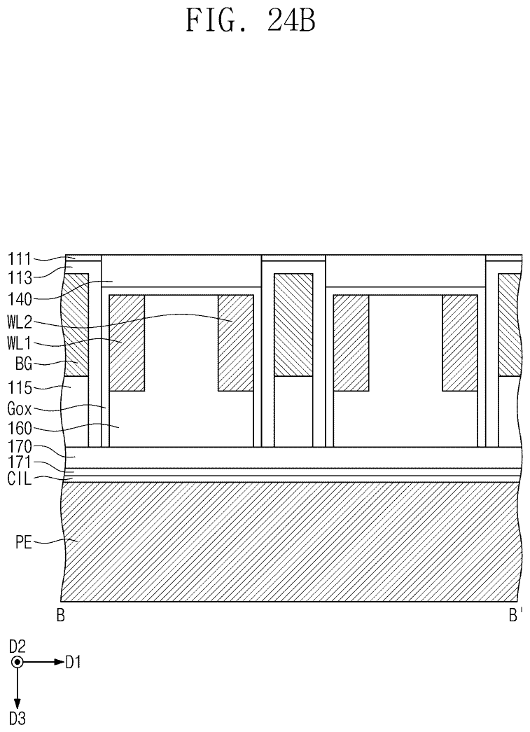

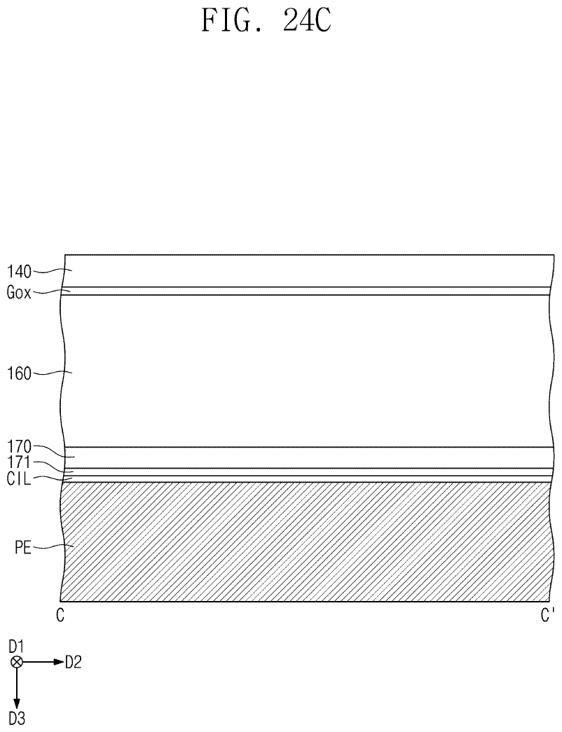

Referring to FIGS. 21 and 24A to 24C, the semiconductor device in fabrication may be inverted. In an embodiment, the first substrate 100, the buried insulating layer 101, and portions of the first insulating patterns 111 may be removed. In an embodiment, the removal of the first substrate 100, the buried insulating layer 101, and the portions of the first insulating patterns 111 may include planarizing the first substrate 100, the buried insulating layer 101, and the portions of the first insulating patterns 111 until the first and second vertical portions V1 and V2 of the semiconductor patterns SP may be exposed.

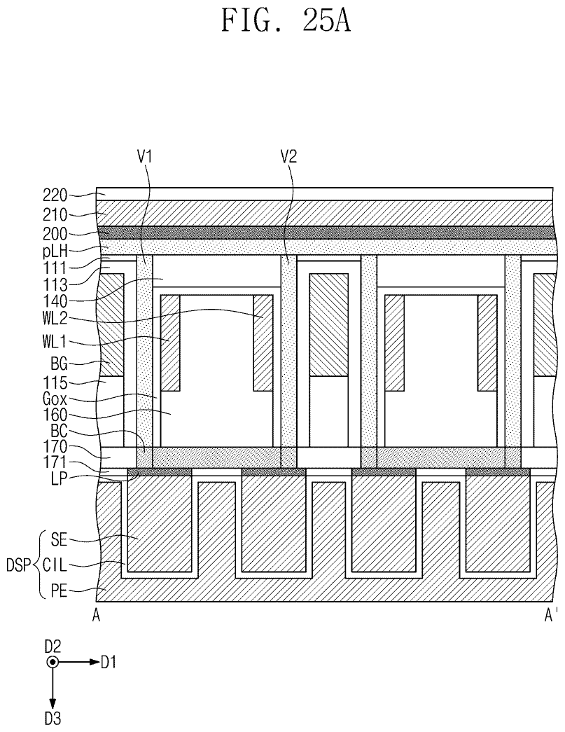

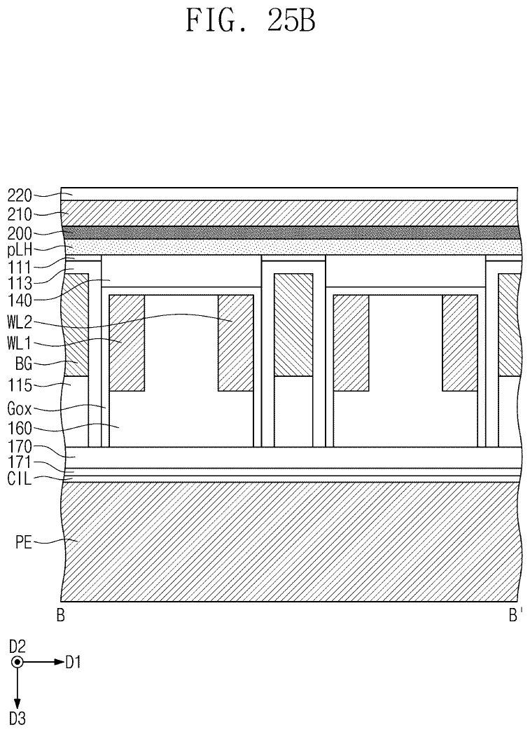

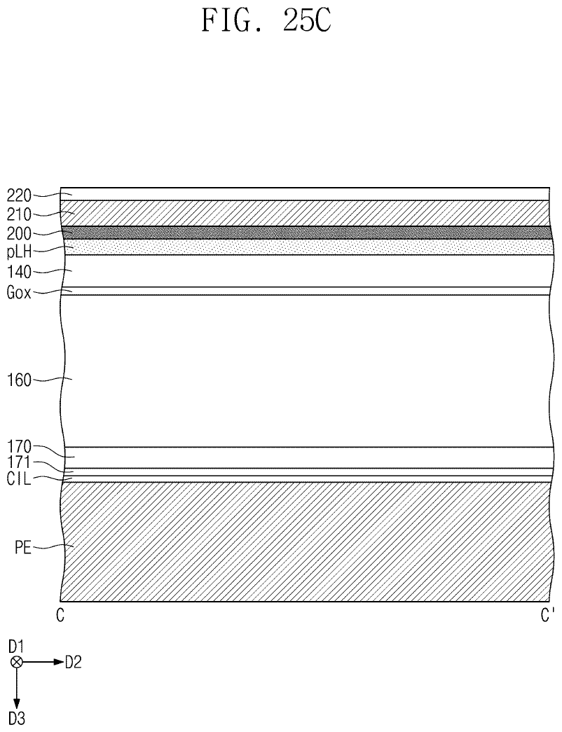

Referring to FIGS. 21 and 25A to 25C, a preliminary line horizontal portion pLH may be formed on the first and second vertical portions V1 and V2, remaining portions of the first insulating patterns 111, and the second insulating pattern 140. The poly-silicon layer 200, the metal layer 210, and the hard mask layer 220 may be sequentially stacked on the preliminary line horizontal portion pLH.

In an embodiment, the line horizontal portion LH and the bit line BL may be formed. In an embodiment, the formation of the line horizontal portion LH and the bit line BL may include forming a mask pattern, etching the hard mask layer 220, the metal layer 210, the poly-silicon layer 200, and the preliminary line horizontal portion pLH using the mask pattern as an etch mask, and removing the mask pattern.

Referring back to FIGS. 21 and 22A to 22C, the first and second insulating layer 240 and 250 and the shielding structures SM may be formed, and the substrate 300 may be bonded thereto. This process may be performed using a substantially similar and/or the same method as the process described with reference to FIGS. 17A to 17C and FIGS. 5A to 5C.

According to an embodiment, a semiconductor pattern may include a horizontal portion. A bottom surface of the horizontal portion may be in direct contact with a bit line. In this case, a contact area between the bit line and the semiconductor pattern may be increased, and a resistance therebetween may be lowered. Accordingly, aspects of the present disclosure provide a semiconductor device with potentially improved electrical and reliability characteristics, when compared to a related semiconductor device.

According to an embodiment, the horizontal portion of the semiconductor pattern may be extended to a region below back-gate electrodes, and in this case, the contact area between the bit line and the semiconductor pattern may be further increased. Accordingly, aspects of the present disclosure provide further improvements in the electrical and reliability characteristics of the semiconductor device, when compared to a related semiconductor device.

While example embodiments of the present disclosure have been particularly shown and described, it is to be understood by one of ordinary skill in the art that variations in form and detail may be made therein without departing from the spirit and scope of the attached claims.

What is claimed is:

1. A semiconductor device, comprising:
a bit line extending in a first direction;
a semiconductor pattern on the bit line, the semiconductor pattern comprising a first vertical portion and a second vertical portion, which are spaced apart from each other in the first direction, and a horizontal portion, which is provided between the first vertical portion and the second vertical portion and is configured to couple the first vertical portion with the second vertical portion;
a first word line and a second word line, which are spaced apart from each other in the first direction between the first vertical portion and the second vertical portion, and are disposed on inner side surfaces of the first vertical portion and the second vertical portion, respectively, and are extended in a second direction; and
back-gate electrodes, which are spaced apart from each other in the first direction with the first vertical portion and the second vertical portion interposed therebetween, and are extended in the second direction,
wherein the first direction and the second direction are parallel to an uppermost surface of the bit line and the first direction and the second direction are non-parallel to each other, and
wherein the back-gate electrodes are disposed on outer side surfaces of the first vertical portion and the second vertical portion, respectively.

2. The semiconductor device of claim 1, wherein the semiconductor pattern comprises a single crystalline semiconductor material.

3. The semiconductor device of claim 1, wherein a bottom surface of the horizontal portion is located at a same height as the uppermost surface of the bit line.

4. The semiconductor device of claim 1, wherein a bottom surface of the horizontal portion is in direct contact with the uppermost surface of the bit line.

5. The semiconductor device of claim 1, wherein a first bottom surface of the first vertical portion and a second bottom surface of the second vertical portion are coplanar with a bottom surface of the horizontal portion.

6. The semiconductor device of claim 1, wherein a bottom surface of the horizontal portion is located at a first height lower than the uppermost surface of the bit line.

7. The semiconductor device of claim 6, further comprising:
back-gate insulating patterns, which are respectively interposed between the back-gate electrodes and the first vertical portion and the second vertical portion,
wherein each of the back-gate insulating patterns is extended into regions between the back-gate electrodes and the bit line.

8. The semiconductor device of claim 6, wherein a first bottom surface of the first vertical portion and a second bottom surface of the second vertical portion are located at a second height lower than the uppermost surface of the bit line.

9. The semiconductor device of claim 1, wherein the horizontal portion is extended into regions between the back-gate electrodes and the bit line.

10. The semiconductor device of claim 9, wherein the horizontal portion and the bit line have a same width in the second direction.

11. The semiconductor device of claim 9, wherein a first bottom surface of the first vertical portion and a second bottom surface of the second vertical portion are located at a height higher than a bottom surface of the horizontal portion.

12. The semiconductor device of claim 9, wherein a bottom surface of the horizontal portion and the uppermost surface of the bit line are in direct contact with each other.

13. The semiconductor device of claim 1, further comprising:
storage node contacts disposed on the first vertical portion and the second vertical portion, respectively;
landing pads disposed on the storage node contacts, respectively; and
data storage patterns disposed on the landing pads, respectively.

14. A semiconductor device, comprising:
a bit line extending in a first direction;
a back-gate electrode provided on the bit line and extended in a second direction to cross the bit line;
a first semiconductor vertical portion and a second semiconductor vertical portion, which are spaced apart from each other in the first direction with the back-gate electrode interposed therebetween;
a first word line, which is spaced apart from the back-gate electrode with the first semiconductor vertical portion interposed therebetween, and is extended in the second direction;
a second word line, which is spaced apart from the back-gate electrode with the second semiconductor vertical portion interposed therebetween, and is extended in the second direction; and
semiconductor horizontal portions, which are respectively extended from a first lower portion of the first semiconductor vertical portion and a second lower portion of the second semiconductor vertical portion into regions between the first word line and the second word line and the bit line.

15. The semiconductor device of claim 14, wherein a first bottom surface of the first semiconductor vertical portion, a second bottom surface of the second semiconductor vertical portion, and bottom surfaces of the semiconductor horizontal portions are in direct contact with an uppermost surface of the bit line.

16. The semiconductor device of claim 14, wherein bottom surfaces of the semiconductor horizontal portions are located at a height lower than an uppermost surface of the bit line.

17. The semiconductor device of claim 14, wherein the semiconductor horizontal portions are extended toward each other or into regions between the back-gate electrode and the bit line to form a single object.

18. A semiconductor device, comprising:
a bit line extending in a first direction;
semiconductor patterns provided on the bit line and spaced apart from each other in the first direction, each of the semiconductor patterns comprising a first vertical portion and a second vertical portion, which are spaced apart from each other in the first direction, and a horizontal portion, which is provided between the first vertical portion and the second vertical portion and is configured to couple the first vertical portion with the second vertical portion;
back-gate electrodes, which are provided between the semiconductor patterns, are extended in a second direction, and are spaced apart from each other in the first direction, the first direction and the second direction being parallel to an uppermost surface of the bit line and being non-parallel to each other;
first word lines, which are respectively disposed adjacent to the first vertical portion and are extended in the second direction;
second word lines, which are respectively disposed adjacent to the second vertical portion and are extended in the second direction;
storage node contacts disposed on the first vertical portion and the second vertical portion, respectively;
landing pads disposed on the storage node contacts, respectively; and
data storage patterns disposed on the landing pads, respectively.

19. The semiconductor device of claim 18, wherein a first bottom surface of the first vertical portion, a second bottom surface of the second vertical portion, and a third bottom surface of the horizontal portion are in direct contact with the uppermost surface of the bit line.

20. The semiconductor device of claim 18, wherein a bottom surface of the horizontal portion is located at a height lower than the uppermost surface of the bit line.
